(19) United States
(12) Patent Application Publication
(10) Pub. No.: US 2007/0066741 A1
(43) Pub. Date: Mar. 22, 2007

(54) High glass transition temperature thermoplastic articles

(76) Inventors: Michael Stephen Donovan, Evansville, IN (US); Robert Russell Gallucci, Mt. Vernon, IN (US); Roy Ray Odle, Mt. Vernon, IN (US); Mark A. Sanner, Newburgh, IN (US); Kapil Chandrakant Sheth, Evansville, IN (US); Rajendra Kashinath Singh, Evansville, IN (US)

Correspondence Address: GEAM - 08CU - ULTEM;IP LEGAL, ONE PLASTICS AVENUE, PITTSFIELD, MA, 01201-3697, US

(21) Appl. No.: 11/320,350

(22) Filed: Dec. 28, 2005

Related U.S. Application Data
(63) Continuation-in-part of application No. 11/228,728, filed on Sep. 16, 2005.
(63) Continuation-in-part of application No. 11/228,729, filed on Sep. 16, 2005.
(63) Continuation-in-part of application No. 11/229,455, filed on Sep. 16, 2005, now abandoned.

(51) Int. Cl. H01L 21/20; C08K 3/22

(52) U.S. Cl. 524/430; 438/487

(57) ABSTRACT

A composite material comprises an electrically conductive material disposed over at least a portion of a substrate wherein the substrate comprises either: a) an immiscible blend of polymers having more than one glass transition temperature and one of the polymers has a glass transition temperature greater than 180 degrees Celsius; b) a miscible blend of polymers having a single glass transition temperature greater than 217 degrees Celsius; or, c) a single virgin polymer having a glass transition temperature of greater than 247 degrees Celsius.

### RELATED APPLICATIONS

The present application is a continuation-in-part of each of the following United States patent applications: U.S. Ser. No. 11/228,728, filed Sep. 16, 2005, in the name of Gallucci et al., titled “Flame Retardant Polysulfone Blends”; U.S. Ser. No. 11/228,729, filed Sep. 16, 2005, in the name of Gallucci et al., titled Flame Retardant Polymer Blends”; and, U.S. Ser. No. 11/229,455, filed Sep. 16, 2005, in the name of Gallucci et al., titled “Improved Polyaryl Ether Ketone Polymer Blends”.

### FIELD OF THE INVENTION

The present invention is directed to electrical components comprising high heat polymers having glass transition temperatures above about 180° C.

### BACKGROUND OF INVENTION

This disclosure relates to articles useful in electronic applications. In particular, the disclosure relates to articles useful in electronic applications wherein the articles comprise a thermoplastic material with a high glass transition temperature.

Electronics are an ever increasing part of our lives and electronic devices are being designed for use in increasingly harsh environments. Consequently the materials employed in electronic devices must be capable of meeting and exceeding the environmental demands. Many electronic devices comprise one or more thermoplastics as an electrically insulating dielectric. The electrically insulating dielectric typically used in conjunction with a metal layer deposited over at least a portion of the electrically insulating dielectric.

One example is printed circuit boards. Printed circuit boards typically comprise a substrate and a metal deposited over the substrate. A multi layer circuit board can comprise multiple layers of substrate and metal. The substrate is an electrically insulating dielectric. The substrate can comprise woven fabrics, non-woven fabrics, and polymeric films. In some cases the electrically insulating dielectric may comprise a laminate of one or more thermoplastic compositions as disclosed in U.S. Patent Application Publication No. 2005/0121226 and U.S. Pat. No. 6,500,529 and U.S. Patent Application Publication No. 2003/0072929. Fluoropolymer and polyetherimide film laminates are suitable for high performance, low loss printed circuit boards that are used in microwave telecommunications and high speed digital processing equipment applications.

Printed circuit boards may be rigid or flexible. Flexible circuit boards may be used in small scale applications such as hearing aids and ink jet cartridges. Flexible printed circuit boards have also recently been used for appliances in telecommunications, and consumer and industrial appliances. As the packaging of those appliances becomes simpler, more compact, more reliable, and more highly functional, restrictions imposed on flexible printed circuit boards become extremely stringent. The boards are required to have high thermal resistance, good weatherability, electric insulation properties, bonding strength, and flexibility, and to meet severe conditions.

Severe conditions include increased heat. The increasing density of circuits and circuit boards has resulted in increasing heat in the interior environment of electronic devices. Additionally, electronic devices are expected to be reliable regardless of the exterior environment they're subjected to—including moisture, heat, cold and the like. Of these, heat presents one of the biggest challenges because the device already generates heat. Accordingly, there is a need in the art for composite materials capable of withstanding elevated temperatures.

### SUMMARY OF THE INVENTION

The aforementioned need is addressed by a composite material comprising an electrically conductive material disposed over at least a portion of a substrate wherein the substrate comprises either: a) an immiscible blend of polymers having more than one glass transition temperature and one of the polymers has a glass transition temperature greater than 180 degrees Celsius; b) a miscible blend of polymers having a single glass transition temperature greater than 217 degrees Celsius; or, c) a single virgin polymer having a glass transition temperature of greater than 247 degrees Celsius.

The present invention is also directed to An electronic part comprising a composite material comprising an electrically conductive material disposed either over or under at least a portion of a substrate or coating respectively, wherein the substrate or coating comprises a material selected from the group consisting of: a) an immiscible blend of polymers comprising one or more polyetherimides, having more than one glass transition temperature wherein the polyetherimide has a glass transition temperature greater than 217° Celsius; b) a miscible blend of polymers, comprising one or more polyetherimides, having a single glass transition temperature greater than 180° Celsius; or, c) a single polyetherimide having a glass transition temperature of greater than 247° Celsius.

### DETAILED DESCRIPTION OF THE INVENTION

“High Tg” refers to polymers having a glass transition temperatures of 180° or above.

The definition of benzylic proton is well known in the art, and in terms of the present invention it encompasses at least one aliphatic carbon atom chemically bonded directly to at least one aromatic ring, such as a phenyl or benzene ring, wherein said aliphatic carbon atom additionally has at least one proton directly bonded to it.

In the present context substantially or essentially free of benzylic protons means that the polymer, such as for example the polyimide sulfone product, has less than about 5 mole % of structural units, in some embodiments less than about 3 mole % structural units, and in other embodiments less than about 1 mole % structural units derived containing benzylic protons. Free of benzylic protons, which are also known as benzylic hydrogens, means that the polyetherimide article has zero mole % of structural units derived from monomers and end cappers containing benzylic protons or benzylic hydrogens. The amount of benzylic protons can be determined by ordinary chemical analysis based on the chemical structure.

The term “hydrogen atom to carbon atom numerical ratio” is the ratio of the number of hydrogen atoms to the number of carbon atoms in the polymer or the repeat unit (monomer) making up the polymer.

The present invention is also directed to shaped articles comprising a polyetherimide having a hydrogen atom number to carbon atom number 0.45-0.85, or 0.50-0.80 or 0.55-0.75 or 0.60-0.70.

Composite materials, as described herein comprise a substrate. The substrate comprises either: a) an immiscible blend of polymers having more than one glass transition temperature and one of the polymers has a glass transition temperature greater than 180 degrees Celsius; b) a miscible blend of polymers having a single glass transition temperature greater than 217 degrees Celsius; or, c) a single virgin polymer having a glass transition temperature of greater than 247 degrees Celsius. The substrate has a low dielectric constant and excellent thermal properties. In addition the substrate has a coefficient of thermal expansion suitable for use in a composite comprising an electrically conductive layer.

In one embodiment, the substrate has a dielectric constant less than or equal to 2.0, or, more specifically, less than or equal to 1.9, 1.8, 1.7, 1.6, 1.5, 1.4, 1.3, 1.2, 1.1, 1.0, 0.9, 0.8, 0.7, 0.6, 0.5, 0.6, 0.5, 0.4, 0.3, 0.2, 0.1 or 0.0.

The substrate may optionally comprise one or more inorganic fillers including solid glass beads, hollow glass beads, glass fibers, a woven glass mat, a non-woven glass, and combinations of two or more of the foregoing as disclosed in U.S. Pat. No. 4,671,984.

The substrate may be treated by one or more methods to improve adhesion. Treatments to improve adhesion include a mechanical treatment, such as brushing and sandblasting, and a chemical treatment, such as an alkali treatment, a corona treatment and a plasma treatment. Exemplary methods and materials are taught in U.S. Pat. Nos. 6,629,348 and 5,234,522.

The electrically conductive material may be disposed on the substrate or an adhesive layer may be disposed between the substrate and the electrically conductive layer. Exemplary materials useful in the adhesive layer include epoxy based materials, polymer precursors, polymer oligomers and acrylic based materials as known in the art. In one embodiment the adhesive layer may be applied to the polymeric substrate by coating a suitable solution onto the substrate and drying. The solution may be comprised of polymer precursors, a mixture of precursors and polymer or just polymer and an organic solvent as disclosed in U.S. Pat. Nos. 6,629,348 and 5,234,522.

The electrically conductive material may be applied by any method known in the art. For example it may be applied as a foil and subsequently etched or milled away. Alternatively, the electrically conductive material maybe sputtered on to the substrate and optional adhesive layer.

When electrically conductive material is applied as a metal foil it is laminated to the substrate surface optionally having an adhesion layer. Alternatively, the adhesion layer may be applied to the metal foil and then the metal foil/adhesion layer combination laminated to the substrate. Lamination may be conducted by autoclave lamination, vacuum hydraulic pressing, non-vacuum hydraulic pressing or by hot roll lamination. Lamination may also be conducted using an ADARA press which comprises heating the metal foil by an amount sufficient to soften the adjacent polymeric material by flowing an electric current through the foil. When using a vacuum press, lamination is typically conducted at a temperature, pressure and time sufficient to form a bond between the electrically conductive material and the substrate.

Exemplary metal foils include copper, zinc, brass, chrome, nickel, aluminum, stainless steel, iron, gold, silver, titanium and combinations and alloys thereof. Usually the metal foil comprises copper. Copper foils are may be produced by electrodepositing copper from solution onto a rotating metal drum as is well known in the art. The metal foil may have a thickness of about 3 micrometers to about 200 micrometers, or, more specifically, about 5 micrometers to about 50 micrometers. Alternatively, wrought copper foils may be used. However, the rolling process is effectively limited to producing foils no thinner than 18 micrometers.

The one or both sides of the metal foil may optionally be roughened, such as by micro-etching, by being electrolytically treated on the shiny side to form a roughened copper deposit, and or by being electrolytically treated on the matte side to include the deposition of micro-nodules of a metal or metal alloy on or in the surface. These nodules are preferably copper or a copper alloy, and increase adhesion to the substrate. The surface microstructure of the foil may be measured by a profilometer, such as a Perthometer model M4P or S5P which is commercially available from Mahr Feinpruef Corporation of Cincinnati, Ohio. Topography measurements of the surface grain structure of peaks and valleys are made according to industry standard IPC-TM-650 Section 2.2.17 of the Institute for Interconnecting and Packaging Circuits of 2115 Sanders Road, Northbrook, Ill. 60062. The surface treatments are carried out to produce a surface structure having peaks and valleys which produce roughness parameters wherein the average roughness (Ra) ranges from about 1 to about 10 microns and the average peak to valley height (Rz) ranges from about 2 to about 10 microns.

After the electrically conductive material is applied to the substrate it may be processed to form the desired circuit pattern resulting in a circuit board. In some cases the electrically conductive material remains substantially continuous. A cover layer may then be applied to protect the circuit pattern. Alternatively the circuit board may be laminated to the substrate of another circuit board or a bond core. The second circuit board may be of the same or different composition as contemplated in U.S. Pat. No. 4,388,136. In one embodiment, the bond core comprises either: a) an immiscible blend of polymers having more than one glass transition temperature and one of the polymers has a glass transition temperature greater than 180 degrees Celsius; b) a miscible blend of polymers having a single glass transition temperature greater than 217 degrees Celsius; or, c) a single virgin polymer having a glass transition temperature of greater than 247 degrees Celsius. When laminating the circuit board to a cover layer, a bond core or another circuit board any or all of the methods discussed above with regard to forming the circuit board may be used.

A protective cover layer may be applied over the electrically conductive layer. In one embodiment, the protective cover layer comprises either: a) an immiscible blend of polymers having more than one glass transition temperature and one of the polymers has a glass transition temperature greater than 180 degrees Celsius; b) a miscible blend of polymers having a single glass transition temperature greater than 217 degrees Celsius; or, c) a single virgin polymer having a glass transition temperature of greater than 247 degrees Celsius.

Representative examples of substrate materials for use in the shell member are listed below:

A. High Tg Polymer Blends of a Sulfone Based Polymer or Blend; a Silicone Co-polymer; and, a Resorcinol Derived Polyaryl Ester.

Disclosed herein are electrical connectors comprising a polymers blend, wherein some or all of one surface of the polymer blend is coated with a covering, wherein the covering material is of a different composition than the polymer blend, and, wherein the polymer blend comprises: a) a first resin selected from the group of polysulfones (PSu), poly(ether sulfone) (PES) poly(phenylene ether sulfone)s (PPSU) having a high glass transition temperature (Tg≧180° C.), b) a silicone copolymer, for instance silicone polyimide or silicone polycarbonate; and optionally, c) a resorcinol based polyarylate, wherein the blend has surprisingly low heat release values.

1. The Polysulfone, Polyether Sulfone and Polyphenylene Ether Sulfone Component of the Blend

Polysulfones, poly(ether sulfone)s and poly(phenylene ether sulfone)s which are useful in the articles described herein are thermoplastic resins described, for example, in U.S. Pat. Nos. 3,634,355, 4,008,203, 4,108,837 and 4,175,175.

Polysulfones, poly(ether sulfone)s and poly(phenylene ether sulfone)s are linear thermoplastic polymers that possess a number of attractive features such as high temperature resistance, good electrical properties, and good hydrolytic stability.

Polysulfones comprise repeating units having the structure of Formula I: 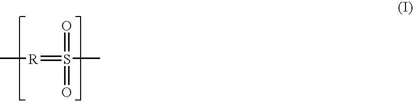
wherein R is an aromatic group comprising carbon-carbon single bonds, carbon-oxygen-carbon bonds or carbon-carbon and carbon-oxygen-carbon single bonds and the single bonds form a portion of the polymer backbone.

Poly(ether sulfone)s comprise repeating units having both an ether linkage and a sulfone linkage in the backbone of the polymer as shown in Formula II: 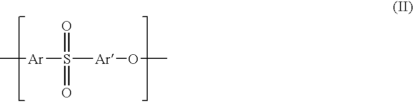
wherein Ar and Ar′ are aromatic groups which may be the same or different. Ar and Ar′ may be the same or different. When Ar and Ar′ are both phenylene the polymer is known as poly(phenylene ether sulfone). When Ar and Ar′ are both arylene the polymer is known as poly(arylene ether sulfone). The number of sulfone linkages and the number of ether linkages may be the same or different. An exemplary structure demonstrating when the number of sulfone linkages differ from the number of ether linkages is shown in Formula (III): 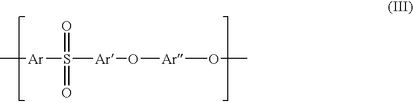
wherein Ar, Ar′ and Ar″ are aromatic groups which may be the same or different. Ar, Ar′ and Ar″ may be the same or different, for instance, Ar and Ar′ may both be phenylene and Ar″ may be a bis(1,4-phenylene)isopropyl group.

A variety of polysulfones and poly(ether sulfone)s are commercially available, including the polycondensation product of dihydroxy diphenyl sulfone with dichloro diphenyl sulfone, and the polycondensation product of bisphenol-A and or biphenol with dichloro diphenyl sulfone. Examples of commercially available resins include RADEL R, RADEL A, and UDEL, available from Solvay, Inc., and ULTRASON E, available from BASF Co.

Methods for the preparation of polysulfones and poly(ether sulfones) are widely known and several suitable processes have been well described in the art. Two methods, the carbonate method and the alkali metal hydroxide method, are known to the skilled artisan. In the alkali metal hydroxide method, a double alkali metal salt of a dihydric phenol is contacted with a dihalobenzenoid compound in the presence of a dipolar, aprotic solvent under substantially anhydrous conditions. The carbonate method, in which a dihydric phenol and a dihalobenzenoid compound are heated, for example, with sodium carbonate or bicarbonate and a second alkali metal carbonate or bicarbonate is also disclosed in the art, for example in U.S. Pat. No. 4,176,222. Alternatively, the polysulfone and poly(ether sulfone) may be prepared by any of the variety of methods known in the art.

The molecular weight of the polysulfone or poly(ether sulfone), as indicated by reduced viscosity data in an appropriate solvent such as methylene chloride, chloroform, N-methylpyrrolidone, or the like, can be greater than or equal to about 0.3 dl/g, or, more specifically, greater than or equal to about 0.4 dl/g and, typically, will not exceed about 1.5 dl/g.

In some instances the polysulfone or poly(ether sulfone) weight average molecular weight can be about 10,000 to about 100,000 as determined by gel permeation chromatography using ASTM METHOD D5296. Polysulfones and poly(ether sulfone)s may have glass transition temperatures of about 180° C. to about 250° C. in some instances. When the polysulfones, poly(ethersulfone)s and poly(phenylene ether sulfone)s are blended with the resins described herein the polysulfone, poly(ether sulfone) and poly(phenylene ether) sulfone will have a glass transition temperature (Tg) greater than or equal to about 180° C. Polysulfone resins are further described in ASTM method D6394 Standard Specification for Sulfone Plastics.

In some instances polysulfones, poly(ethersulfone)s and poly(phenylene ether sulfone)s and blends thereof, will have a hydrogen to carbon atom ratio (H/C) of less than or equal to about 0.85. Without being bound by theory polymers with higher carbon content relative to hydrogen content, that is a low ratio of hydrogen to carbon atoms, often show improved FR performance. These polymers have lower fuel value and may give off less energy when burned. They may also resist burning through a tendency to form an insulating char layer between the polymeric fuel and the source of ignition. Independent of any specific mechanism or mode of action it has been observed that such polymers, with a low H/C ratio, have superior flame resistance. In some instances the H/C ratio can be less than or equal to 0.75 or less than 0.65. In other instances a H/C ratio of greater than or equal to about 0.4 is preferred in order to give polymeric structures with sufficient flexible linkages to achieve melt processability. The H/C ratio of a given polymer or copolymer can be determined from its chemical structure by a count of carbon and hydrogen atoms independent of any other atoms present in the chemical repeat unit.

In the polymer blend the polysulfones, poly(ether sulfone)s and poly(phenylene ether sulfone)s and blends thereof may be present in amounts of about 1 to about 99 weight percent, based on the total weight of the polymer blend. Within this range, the amount of the polysulfones, poly(ether sulfone)s, and poly(phenylene ether sulfone)s and mixtures thereof may be greater than or equal to about 20 weight percent, more specifically greater than or equal to about 50 weight percent, and even more specifically greater than or equal to about 70 weight percent. The skilled artisan will appreciate that the polysulfones, poly(ether sulfones), and poly(phenylene ether sulfone)s and mixtures thereof may be present in a percentage by weight of the total polymer blend of any real number between about 1 and about 99 weight percent, and particularly from 1 to 70 weight percent.

2. The Silicone Component of the Blend

The silicone copolymer comprises any siloxane copolymer effective to improve the heat release performance of the composition. In some instances siloxane copolymers of polyetherimides, polyetherimide sulfones, polysulfones, poly(phenylene ether sulfone)s, poly(ether sulfone)s or poly(phenylene ether)s maybe used. In some instances, siloxane polyetherimide copolymers, or siloxane polycarbonate copolymers may be effective in reducing heat release and improving flow rate performance. Mixtures of different types of siloxane copolymers are also contemplated. In one embodiment, the siloxane copolymer comprises about 5 to about 70 wt % and in other instances 20 to about 50 wt % siloxane content with respect to the total weight of the copolymer.

The block length of the siloxane segment of the copolymer may be of any effective length. In some examples, the block length may be about 2 to about 70 siloxane repeating units. In other instances the siloxane block length may be about 5 to about 50 repeating units. In many instances dimethyl siloxanes may be used.

Siloxane polyetherimide copolymers are a specific embodiment of the siloxane copolymer that may be used in the polymer blend. Examples of such siloxane polyetherimide copolymers are shown in U.S. Pat. Nos. 4,404,350, 4,808,686 and 4,690,997. In one instance the siloxane polyetherimide copolymer can be prepared in a manner similar to that used for polyetherimides, except that a portion, or all, of the organic diamine reactant is replaced by an amine-terminated organo siloxane, for example, of Formula IV wherein g is an integer having a value of 1 to about 50, or, more specifically, about 5 to about 30 and R′ is an aryl, alkyl or aryl alky group having 2 to about 20 carbon atoms.

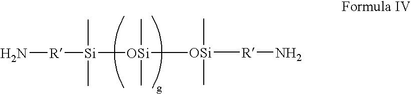

The siloxane polyetherimide copolymer can be prepared by any of the methods well known to those skilled in the art, including the reaction of an aromatic bis(ether anhydride) of the Formula V 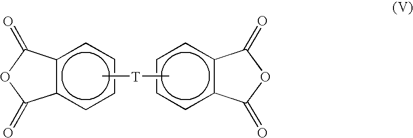
wherein T is —O—, —S—, —SO₂— or a group of the formula —O-Z-O— wherein the divalent bonds of the —O— or the —O-Z-O— group are in the 3,3′, 3,4′, 4,3′, or the 4,4′ positions, and wherein Z includes, but is not limited to substituted or unsubstituted divalent organic radicals such as: (a) aromatic hydrocarbon radicals having about 6 to about 20 carbon atoms and halogenated derivatives thereof; (b) straight or branched chain alkylene radicals having about 2 to about 20 carbon atoms; (c) cycloalkylene radicals having about 3 to about 20 carbon atoms, or (d) divalent radicals of the general Formula VI 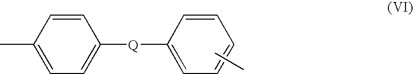
wherein Q includes but is not limited to a divalent group selected from the group consisting of —O—, —S—, —C(O)—, —SO₂—, —SO—, —C_{y}H_{2y}— (y being an integer from 1 to 8), and fluorinated derivatives thereof, including perfluoroalkylene groups, with an organic diamine of the formula VII
H₂N—R¹—NH₂ (VII)
wherein group R¹ in formula VII includes, but is not limited to, substituted or unsubstituted divalent organic radicals such as: (a) aromatic hydrocarbon radicals having about 6 to about 24 carbon atoms and halogenated derivatives thereof; (b) straight or branched chain alkylene radicals having about 2 to about 20 carbon atoms; (c) cycloalkylene radicals having about 3 to about 20 carbon atoms, or (d) divalent radicals of the general formula VI.

Examples of specific aromatic bis anhydrides and organic diamines are disclosed, for example, in U.S. Pat. Nos. 3,972,902 and 4,455,410. Illustrative examples of aromatic bis anhydride of formula (XIV) include:
3,3-bis[4-(3,4-dicarboxyphenoxy)phenyl]propane dianhydride;
4,4′-bis(3,4-dicarboxyphenoxy)diphenyl ether dianhydride;
4,4′-bis(3,4-dicarboxyphenoxy)diphenyl sulfide dianhydride;
4,4′-bis(3,4-dicarboxyphenoxy)benzophenone dianhydride;
4,4′-bis(3,4-dicarboxyphenoxy)diphenyl sulfone dianhydride;
2,2-bis[4-(2,3-dicarboxyphenoxy)phenyl]propane dianhydride;
4,4′-bis(2,3-dicarboxyphenoxy)diphenyl ether dianhydride;
4,4′-bis(2,3-dicarboxyphenoxy)diphenyl sulfide dianhydride;
4,4′-bis(2,3-dicarboxyphenoxy)benzophenone dianhydride;
4,4′-bis(2,3-dicarboxyphenoxy)diphenyl sulfone dianhydride;
4-(2,3-dicarboxyphenoxy)-4′-(3,4-dicarboxyphenoxy)diphenyl-2,2-propane dianhydride;
4-(2,3-dicarboxyphenoxy)-4′-(3,4-dicarboxyphenoxy)diphenyl ether dianhydride;
4-(2,3-dicarboxyphenoxy)-4′-(3,4-dicarboxyphenoxy)diphenyl sulfide dianhydride;
4-(2,3-dicarboxyphenoxy)-4′-(3,4-dicarboxyphenoxy)benzophenone dianhydride; and,
4-(2,3-dicarboxyphenoxy)-4′-(3,4-dicarboxyphenoxy)diphenyl sulfone dianhydride,

as well as mixtures thereof.

Examples of suitable diamines, in addition to the siloxane diamines described above, include ethylenediamine, propylenediamine, trimethylenediamine, diethylenetriamine, triethylenetertramine, hexamethylenediamine, heptamethylenediamine, octamethylenediamine, nonamethylenediamine, decamethylenediamine, 1,12-dodecanediamine, 1,18-octadecanediamine, 3-methylheptamethylenediamine, 4,4-dimethylheptamethylenediamine, 4-methylnonamethylenediamine, 5-methylnonamethylenediamine, 2,5-dimethylhexamethylenediamine, 2,5-dimethylheptamethylenediamine, 2,2-dimethylpropylenediamine, N-methyl-bis(3-aminopropyl)amine, 3-methoxyhexamethylenediamine, 1,2-bis(3-aminopropoxy)ethane, bis(3-aminopropyl)sulfide, 1,4-cyclohexanediamine, bis-(4-aminocyclohexyl)methane, m-phenylenediamine, p-phenylenediamine, 2,4-diaminotoluene, 2,6-diaminotoluene, m-xylylenediamine, p-xylylenediamine, 2-methyl-4,6-diethyl-1,3-phenylene-diamine, 5-methyl-4,6-diethyl-1,3-phenylene-diamine, benzidine, 3,3′-dimethylbenzidine, 3,3′-dimethoxybenzidine, 1,5-diaminonaphthalene, bis(4-aminophenyl)methane, bis(2-chloro-4-amino-3,5-diethylphenyl)methane, bis(4-aminophenyl)propane, 2,4-bis(amino-t-butyl)toluene, bis(p-amino-t-butylphenyl)ether, bis(p-methyl-o-aminophenyl)benzene, bis(p-methyl-o-aminopentyl)benzene, 1,3-diamino-4-isopropylbenzene, bis(4-aminophenyl)sulfide, bis(4-aminophenyl)sulfone, bis(4-aminophenyl)ether and combinations comprising two or more of the foregoing. A specific example of a siloxane diamine is 1,3-bis(3-aminopropyl)tetramethyldisiloxane. In one embodiment the diamino compounds used in conjunction with the siloxane diamine are aromatic diamines, especially m- and p-phenylenediamine, sulfonyl dianiline and mixtures thereof.

Some siloxane polyetherimide copolymers may be formed by reaction of an organic diamine, or mixture of diamines, of formula VII and the amine-terminated organo siloxane of formula IV as mentioned above. The diamino components may be physically mixed prior to reaction with the bis-anhydride(s), thus forming a substantially random copolymer. Alternatively block or alternating copolymers may be formed by selective reaction of VII and IV with dianhydrides, for example those of formula V, to make polyimide blocks that are subsequently reacted together. In another instance the siloxane used to prepare the polyetherimde copolymer may have anhydride rather than amine functional end groups.

In one instance the siloxane polyetherimide copolymer can be of formula VIII wherein T, R′ and g are described as above, b has a value of about 5 to about 100 and Ar¹ is an aryl or alkyl aryl group having 6 to about 36 carbons.

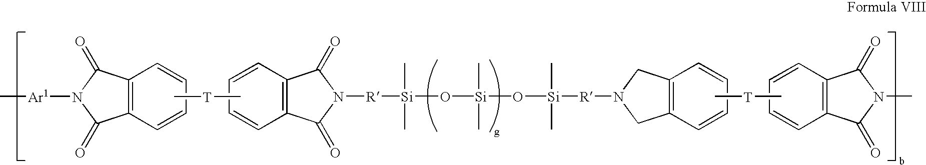

In some siloxane polyetherimide copolymers the diamine component of the siloxane polyetherimide copolymers may contain about 20 to 50 mole % of the amine-terminated organo siloxane of formula IV and about 50 to 80 mole % of the organic diamine of formula VII. In some siloxane copolymers, the siloxane component is derived from about 25 to about 40 mole % of an amine or anhydride terminated organo siloxane.

The silicone copolymer component of the polymer blend may be present in an amount of about 0.1 to about 40 weight percent or alternatively from about 0.1 to about 20 weight percent with respect to the total weight of the polymer blend. Within this range, the silicone copolymer may also be present in an amount 0.1 to about 10%, further from 0.5 to about 5.0%.

3. The Resorcinol Based Polyarylate Component of the Blend

The resorcinol based polyarylate is a polymer comprising arylate polyester structural units that are the reaction product of a diphenol and an aromatic dicarboxylic acid. At least a portion of the arylate polyester structural units comprise a 1,3-dihydroxybenzene group, as illustrated in Formula I, commonly referred to throughout this specification as resorcinol or resorcinol group. Resorcinol or resorcinol group as used herein should be understood to include both unsubstituted 1,3-dihydroxybenzene and substituted 1,3-dihydroxybenzenes unless explicitly stated otherwise.

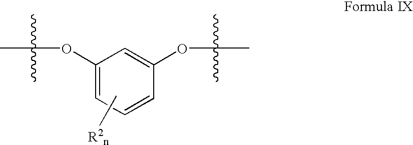

In Formula IX R² is independently at each occurrence a C₁₋₁₂ alkyl, C₆-C₂₄ aryl, C₇-C₂₄ alkyl aryl, alkoxy or halogen, and n is 0-4.

In one embodiment, the resorcinol based polyarylate resin comprises greater than or equal to about 50 mole % of units derived from the reaction product of resorcinol with an aryl dicarboxylic acid or aryl dicarboxylic acid derivative suitable for the formation of aryl ester linkages, for example, carboxylic acid halides, carboxylic acid esters and carboxylic acid salts.

Suitable dicarboxylic acids include monocyclic and polycyclic aromatic dicarboxylic acids. Exemplary monocyclic dicarboxylic acids include isophthalic acid, terephthalic acid, or mixtures of isophthalic and terephthalic acids. Polycyclic dicarboxylic acids include diphenyl dicarboxylic acid, diphenylether dicarboxylic acid, and naphthalenedicarboxylic acid, for example naphthalene-2,6-dicarboxylic acid.

Therefore, in one embodiment the polymer blend comprises a thermally stable polymers having resorcinol arylate polyester units as illustrated in Formula X wherein R² and n are as previously defined:

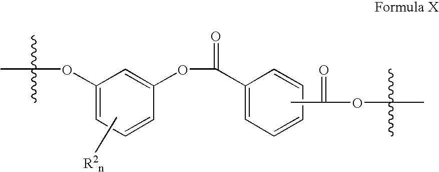

Polymers comprising resorcinol arylate polyester units may be made by an interfacial polymerization method. To prepare polymers comprising resorcinol arylate polyester units substantially free of anhydride linkages a method can be employed wherein the first step combines a resorcinol group and a catalyst in a mixture of water and an organic solvent substantially immiscible with water. Suitable resorcinol compounds are of Formula XI: 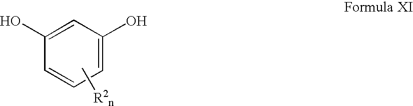
wherein R² is independently at each occurrence C₁₋₁₂ alkyl, C₆-C₂₄ aryl, C₇-C₂₄ alkyl aryl, alkoxy or halogen, and n is 0-4. Alkyl groups, if present, are typically straight-chain, branched, or cyclic alkyl groups, and are most often located in the ortho position to both oxygen atoms although other ring locations are contemplated. Suitable C₁₋₁₂ alkyl groups include, but are not limited to, methyl, ethyl, n-propyl, isopropyl, butyl, iso-butyl, t-butyl, hexyl, cyclohexyl, nonyl, decyl, and aryl-substituted alkyl, including benzyl. In a particular embodiment an alkyl group is methyl. Suitable halogen groups are bromo, chloro, and fluoro. The value for n in various embodiments may be 0 to 3, in some embodiments 0 to 2, and in still other embodiments 0 to 1. In one embodiment the resorcinol group is 2-methylresorcinol. In another embodiment the resorcinol group is an unsubstituted resorcinol group in which n is zero. The method further comprises combining one catalyst with the reaction mixture. Said catalyst may be present in various embodiments at a total level of 0.01 to 10 mole %, and in some embodiments at a total level of 0.2 to 6 mole % based on total molar amount of acid chloride groups. Suitable catalysts comprise tertiary amines, quaternary ammonium salts, quaternary phosphonium salts, hexaalkylguanidinium salts, and mixtures thereof.

Suitable dicarboxylic acid dihalides may comprise aromatic dicarboxylic acid dichlorides derived from monocyclic moieties, illustrative examples of which include isophthaloyl dichloride, terephthaloyl dichloride, or mixtures of isophthaloyl and terephthaloyl dichlorides. Suitable dicarboxylic acid dihalides may also comprise aromatic dicarboxylic acid dichlorides derived from polycyclic moieties, illustrative examples of which include diphenyl dicarboxylic acid dichloride, diphenylether dicarboxylic acid dichloride, and naphthalenedicarboxylic acid dichloride, especially naphthalene-2,6-dicarboxylic acid dichloride; or from mixtures of monocyclic and polycyclic aromatic dicarboxylic acid dichlorides. In one embodiment the dicarboxylic acid dichloride comprises mixtures of isophthaloyl and/or terephthaloyl dichlorides as typically illustrated in Formula XII.

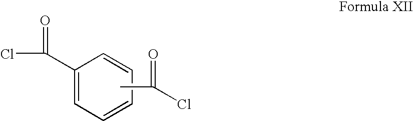

Either or both of isophthaloyl and terephthaloyl dichlorides may be present. In some embodiments the dicarboxylic acid dichlorides comprise mixtures of isophthaloyl and terephthaloyl dichloride in a molar ratio of isophthaloyl to terephthaloyl of about 0.25-4.0:1; in other embodiments the molar ratio is about 0.4-2.5:1; and in still other embodiments the molar ratio is about 0.67-1.5:1.

Dicarboxylic acid halides provide only one method of preparing the polymers mentioned herein. Other routes to make the resorcinol arylate linkages are also contemplated using, for example, the dicarboxylic acid, a dicarboxylic acid ester, especially an activated ester, or dicarboxylate salts or partial salts.

A one chain-stopper (also referred to sometimes hereinafter as capping agent) may also be used. A purpose of adding a chain-stopper is to limit the molecular weight of polymer comprising resorcinol arylate polyester chain members, thus providing polymer with controlled molecular weight and favorable processability. Typically, a chain-stopper is added when the resorcinol arylate-containing polymer is not required to have reactive end-groups for further application. In the absence of chain-stopper resorcinol arylate-containing polymer may be either used in solution or recovered from solution for subsequent use such as in copolymer formation which may require the presence of reactive end-groups, typically hydroxy, on the resorcinol-arylate polyester segments. A chain-stopper may be a mono-phenolic compound, a mono-carboxylic acid chloride, a mono-chloroformates or a combination of two or more of the foregoing. Typically, the chain-stopper may be present in quantities of 0.05 to 10 mole %, based on resorcinol in the case of mono-phenolic compounds and based on acid dichlorides in the case mono-carboxylic acid chlorides and/or mono-chloroformates.

Suitable mono-phenolic compounds include monocyclic phenols, such as phenol, C₁-C₂₂ alkyl-substituted phenols, p-cumyl-phenol, p-tertiary-butyl phenol, hydroxy diphenyl; monoethers of diphenols, such as p-methoxyphenol. Alkyl-substituted phenols include those with branched chain alkyl substituents having 8 to 9 carbon atoms as described in U.S. Pat. No. 4,334,053. In some embodiments mono-phenolic chain-stoppers are phenol, p-cumylphenol, and resorcinol monobenzoate.

Suitable mono-carboxylic acid chlorides include monocyclic, mono-carboxylic acid chlorides, such as benzoyl chloride, C₁-C₂₂ alkyl-substituted benzoyl chloride, toluoyl chloride, halogen-substituted benzoyl chloride, bromobenzoyl chloride, cinnamoyl chloride, 4-nadimidobenzoyl chloride, and mixtures thereof; polycyclic, mono-carboxylic acid chlorides, such as trimellitic anhydride chloride, and naphthoyl chloride; and mixtures of monocyclic and polycyclic mono-carboxylic acid chlorides. The chlorides of aliphatic monocarboxylic acids with up to 22 carbon atoms are also suitable. Functionalized chlorides of aliphatic monocarboxylic acids, such as acryloyl chloride and methacryoyl chloride, are also suitable. Suitable mono-chloroformates include monocyclic, mono-chloroformates, such as phenyl chloroformate, alkyl-substituted phenyl chloroformate, p-cumyl phenyl chloroformate, toluene chloroformate, and mixtures thereof.

A chain-stopper can be combined together with the resorcinol, can be contained in the solution of dicarboxylic acid dichlorides, or can be added to the reaction mixture after production of a precondensate. If mono-carboxylic acid chlorides and/or mono-chloroformates are used as chain-stoppers, they are often introduced together with dicarboxylic acid dichlorides. These chain-stoppers can also be added to the reaction mixture at a moment when the chlorides of dicarboxylic acid have already reacted substantially or to completion. If phenolic compounds are used as chain-stoppers, they can be added in one embodiment to the reaction mixture during the reaction, or, in, another embodiment, before the beginning of the reaction between resorcinol and acid dichloride. When hydroxy-terminated resorcinol arylate-containing precondensate or oligomers are prepared, then chain-stopper may be absent or only present in small amounts to aid control of oligomer molecular weight.

In another embodiment a branching agent such as a trifunctional or higher functional carboxylic acid chloride and/or trifunctional or higher functional phenol may be included. Such branching agents, if included, can typically be used in quantities of 0.005 to 1 mole %, based on dicarboxylic acid dichlorides or resorcinol used, respectively. Suitable branching agents include, for example, trifunctional or higher carboxylic acid chlorides, such as trimesic acid tri acid chloride, 3,3′,4,4′-benzophenone tetracarboxylic acid tetrachloride, 1,4,5,8-naphthalene tetracarboxylic acid tetrachloride or pyromellitic acid tetrachloride, and trifunctional or higher phenols, such as 4,6-dimethyl-2,4,6-tri-(4-hydroxyphenyl)-2-heptene, 4,6-dimethyl-2,4,6-tri-(4-hydroxyphenyl)-heptane, 1,3,5-tri-(4-hydroxyphenyl)-benzene, 1,1,1-tri-(4-hydroxyphenyl)-ethane, tri-(4-hydroxyphenyl)-phenyl methane, 2,2-bis-[4,4-bis-(4-hydroxyphenyl)-cyclohexyl]-propane, 2,4-bis-(4-hydroxyphenylisopropyl)-phenol, tetra-(4-hydroxyphenyl)-methane, 2,6-bis-(2-hydroxy-5-methylbenzyl)-4-methyl phenol, 2-(4-hydroxyphenyl)-2-(2,4-dihydroxyphenyl)-propane, tetra-(4-[4-hydroxyphenylisopropyl]-phenoxy)-methane, 1,4-bis-[(4,4-dihydroxytriphenyl)methyl]-benzene. Phenolic branching agents may be introduced first with the resorcinol moieties while acid chloride branching agents may be introduced together with acid dichlorides.

In one of its embodiments articles of manufacture comprise thermally stable resorcinol acrylate polyesters made by the described method and substantially free of anhydride linkages linking at least two mers of the polyester chain. In a particular embodiment said polyesters comprise dicarboxylic acid residues derived from a mixture of iso- and terephthalic acids as illustrated in Formula XIII: 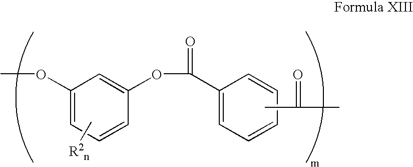
wherein R² is independently at each occurrence a C₁₋₂ alkyl, C₆-C₂₄ aryl, alkyl aryl, alkoxy or halogen, n is 0-4, and m is greater than or equal to about 5. In various embodiments n is zero and m is about 10 to about 300. The molar ratio of isophthalate to terephthalate is in one embodiment about 0.25-4.0:1, in another embodiment about 0.4-2.5:1, and in still another embodiment about 0.67-1.5:1. Substantially free of anhydride linkages means that said polyesters show decrease in molecular weight in one embodiment of less than 30% and in another embodiment of less than 10% upon heating said polymer at a temperature of about 280-290° C. for five minutes.

Also included are articles comprising a resorcinol arylate copolyesters containing soft-block segments as disclosed in commonly owned U.S. Pat. No. 5,916,997. The term soft-block as used herein, indicates that some segments of the polymers are made from non-aromatic monomer units. Such non-aromatic monomer units are generally aliphatic and are known to impart flexibility to the soft-block-containing polymers. The copolymers include those comprising structural units of Formulas IX, XIV, and XV: 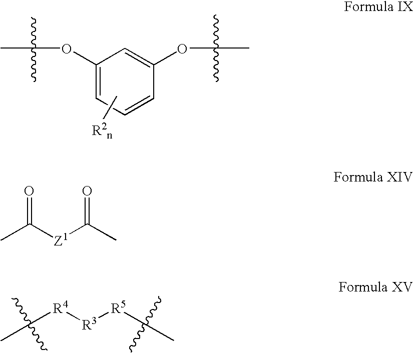
wherein R² and n are as previously defined, Z¹ is a divalent aromatic radical, R³ is a C₃₋₂₀ straight chain alkylene, C₃₋₁₀ branched alkylene, or C₄₋₁₀ cyclo- or bicycloalkylene group, and R⁴ and R⁵ each independently represent 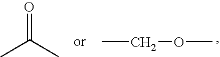
wherein Formula XV contributes about 1 to about 45 mole percent to the ester linkages of the polyester. Additional embodiments provide a composition wherein Formula XV contributes in various embodiments about 5 to about 40 mole percent to the ester linkages of the polyester, and in other embodiments about 5 to about 20 mole percent to the ester linkages of the polyester. Another embodiment provides a composition wherein R³ represents in one embodiment C₃₋₁₄ straight chain alkylene, or C₅₋₆ cycloalkylene, and in another embodiment R³ represents C₃₋₁₀ straight-chain alkylene or C₆-cycloalkylene. Formula XIV represents an aromatic dicarboxylic acid residue. The divalent aromatic radical Z¹ in Formula XIV may be derived in various embodiments from a suitable dicarboxylic acid residues as defined hereinabove, and in some embodiments comprises 1,3-phenylene, 1,4-phenylene, or 2,6-naphthylene or a combination of two or more of the foregoing. In various embodiments Z¹ comprises greater than or equal to about 40 mole percent 1,3-phenylene. In various embodiments of copolyesters containing soft-block chain members n in Formula IX is zero.

In another of its embodiments the resorcinol based polyarylate can be a block copolyestercarbonate comprising resorcinol arylate-containing block segments in combination with organic carbonate block segments. The segments comprising resorcinol arylate chain members in such copolymers are substantially free of anhydride linkages. Substantially free of anhydride linkages means that the copolyestercarbonates show decrease in molecular weight in one embodiment of less than 10% and in another embodiment of less than 5% upon heating said copolyestercarbonate at a temperature of about 280-290° C. for five minutes.

The carbonate block segments contain carbonate linkages derived from reaction of a bisphenol and a carbonate forming species, such as phosgene, making a polyester carbonate copolymer. For example, the resorcinol polyarylate carbonate copolymers can comprise the reaction products of iso- and terephthalic acid, resorcinol and bisphenol A and phosgene. The resorcinol polyester carbonate copolymer can be made in such a way that the number of bisphenol dicarboxylic ester linkages is minimized, for example by pre-reacting the resorcinol with the dicarboxylic acid to form an aryl polyester block and then reacting a said block with the bisphenol and carbonate to form the polycarbonate part of the copolymer.

For best effect, resorcinol ester content (REC) in the resorcinol polyester carbonate should be greater than or equal to about 50 mole % of the polymer linkages being derived from resorcinol. In some instances REC of greater than or equal to about 75 mole %, or even as high as about 90 or 100 mole % resorcinol derived linkages may be desired depending on the application.

The block copolyestercarbonates include those comprising alternating arylate and organic carbonate blocks, typically as illustrated in Formula XVI, wherein R² and n are as previously defined, and R⁶ is a divalent organic radical:

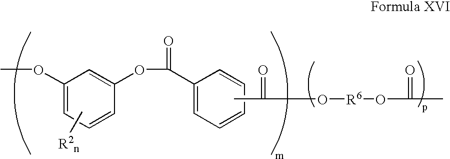

The arylate blocks have a degree of polymerization (DP), represented by m, that is in one embodiment greater than or equal to about 4, in another embodiment greater than or equal to about 10, in another embodiment greater than or equal to about 20 and in still another embodiment about 30 to about 150. The DP of the organic carbonate blocks, represented by p, is in one embodiment greater than or equal to about 2, in another embodiment about 10 to about 20 and in still another embodiment about 2 to about 200. The distribution of the blocks may be such as to provide a copolymer having any desired weight proportion of arylate blocks in relation to carbonate blocks. In general, the content of arylate blocks is in one embodiment about 10 to about 95% by weight and in another embodiment about 50 to about 95% by weight with respect to the total weight of the polymer.

Although a mixture of iso- and terephthalate is illustrated in Formula XVI, the dicarboxylic acid residues in the arylate blocks may be derived from any suitable dicarboxylic acid residue, as defined hereinabove, or mixture of suitable dicarboxylic acid residues, including those derived from aliphatic diacid dichlorides (so-called “soft-block” segments). In various embodiments n is zero and the arylate blocks comprise dicarboxylic acid residues derived from a mixture of iso- and terephthalic acid residues, wherein the molar ratio of isophthalate to terephthalate is in one embodiment about 0.25 to 4.0:1, in another embodiment about 0.4 to 2.5:1, and in still another embodiment about 0.67 to 1.5:1.

In the organic carbonate blocks, each R⁶ is independently at each occurrence a divalent organic radical. In various embodiments said radical comprises a dihydroxy-substituted aromatic hydrocarbon, and greater than or equal to about 60 percent of the total number of R⁶ groups in the polymer are aromatic organic radicals and the balance thereof are aliphatic, alicyclic, or aromatic radicals. Suitable R⁶ radicals include m-phenylene, p-phenylene, 4,4′-biphenylene, 4,4′-bi(3,5-dimethyl)-phenylene, 2,2-bis(4-phenylene)propane, 6,6′-(3,3,3′,3′-tetramethyl-1,1′-spirobi[1H-indan]) and similar radicals such as those which correspond to the dihydroxy-substituted aromatic hydrocarbons disclosed by name or formula (generic or specific) in U.S. Pat. No. 4,217,438.

In some embodiments each R⁶ is an aromatic organic radical and in other embodiments a radical of Formula XVII:
A¹-Y-A² Formula XVII
wherein each A¹ and A² is a monocyclic divalent aryl radical and Y is a bridging radical in which one or two carbon atoms separate A¹ and A². The free valence bonds in Formula XVII are usually in the meta or para positions of A¹ and A² in relation to Y. Compounds in which R⁶ has Formula XVII are bisphenols, and for the sake of brevity the term “bisphenol” is sometimes used herein to designate the dihydroxy-substituted aromatic hydrocarbons. It should be understood, however, that non-bisphenol compounds of this type may also be employed as appropriate.

In Formula XVII, A¹ and A² typically represent unsubstituted phenylene or substituted derivatives thereof, illustrative substituents (one or more) being alkyl, alkenyl, and halogen (particularly bromine). In one embodiment unsubstituted phenylene radicals are preferred. Both A¹ and A² are often p-phenylene, although both may be o- or m-phenylene or one o- or m-phenylene and the other p-phenylene.

The bridging radical, Y, is one in which one or two atoms, separate A¹ from A². In a particular embodiment one atom separates A¹ from A². Illustrative radicals of this type are —O—, —S—, —SO— or —SO₂—, methylene, cyclohexyl methylene, 2-[2.2.1]-bicycloheptyl methylene, ethylene, isopropylidene, neopentylidene, cyclohexylidene, cyclopentadecylidene, cyclododecylidene, adamantylidene, and like radicals.

In some embodiments gem-alkylene (commonly known as “alkylidene”) radicals are preferred. Also included, however, are unsaturated radicals. In some embodiments the bisphenol is 2,2-bis(4-hydroxyphenyl)propane (bisphenol-A or BPA), in which Y is isopropylidene and A¹ and A² are each p-phenylene. Depending upon the molar excess of resorcinol present in the reaction mixture, R⁶ in the carbonate blocks may at least partially comprise resorcinol group. In other words, in some embodiments carbonate blocks of Formula X may comprise a resorcinol group in combination with at least one other dihydroxy-substituted aromatic hydrocarbon.

Diblock, triblock, and multiblock copolyestercarbonates are included. The chemical linkages between blocks comprising resorcinol arylate chain members and blocks comprising organic carbonate chain members may comprise at least one of (a) an ester linkage between a suitable dicarboxylic acid residue of an arylate group and an —O—R⁶—O— group of an organic carbonate group, for example as typically illustrated in Formula XVIII, wherein R⁶ is as previously defined: 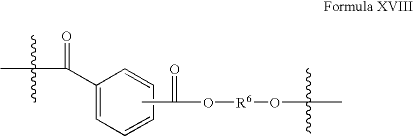
and

(b) a carbonate linkage between a diphenol residue of a resorcinol arylate group and a [symbol] C═O)—O— group of an organic carbonate group as shown in Formula XIX, wherein R² and n are as previously defined:

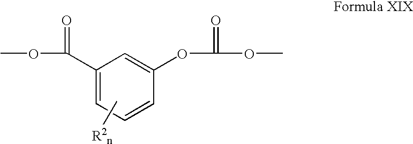

In one embodiment the copolyestercarbonate is substantially comprised of a diblock copolymer with a carbonate linkage between resorcinol arylate block and an organic carbonate block. In another embodiment the copolyestercarbonate is substantially comprised of a triblock carbonate-ester-carbonate copolymer with carbonate linkages between the resorcinol arylate block and organic carbonate end-blocks.

Copolyestercarbonates with a carbonate linkage between a thermally stable resorcinol arylate block and an organic carbonate block are typically prepared from resorcinol arylate-containing oligomers and containing in one embodiment at least one and in another embodiment at least two hydroxy-terminal sites. Said oligomers typically have weight average molecular weight in one embodiment of about 10,000 to about 40,000, and in another embodiment of about 15,000 to about 30,000. Thermally stable copolyestercarbonates may be prepared by reacting said resorcinol arylate-containing oligomers with phosgene, a chain-stopper, and a dihydroxy-substituted aromatic hydrocarbon in the presence of a catalyst such as a tertiary amine.

In one instance articles can comprise a blend of a resin selected from the group consisting of: polysulfones, poly(ethersulfone)s and poly(phenylene ether sulfone)s, and mixtures thereof; a silicone copolymer and a resorcinol based polyarylate wherein greater than or equal to 50 mole % of the aryl polyester linkages are aryl ester linkages derived from resorcinol.

The amount of resorcinol based polyarylate used in the polymer blends used to make articles can vary widely depending on the end use of the article. For example, when the article will be used in an end use where heat release or increase time to peak heat release are important, the amount of resorcinol ester containing polymer can be maximized to lower the heat release and lengthen the time period to peak heat release. In some instances resorcinol based polyarylate can be about 1 to about 50 weight percent of the polymer blend. Some compositions of note will have about 10 to about 50 weight percent resorcinol based polyarylate with respect to the total weight of the polymer blend.

In another embodiment, an article comprising a polymer blend of;

a) about 1 to about 99% by weight of a polysulfones, poly(ether sulfone)s and poly(phenylene ether sulfone)s or mixtures thereof;

b) about 0.1 to about 30% by weight of silicone copolymer;

c) about 99 to about 1% by weight of a resorcinol based polyarylate containing greater than or equal to about 50 mole % resorcinol derived linkages;

d) 0 to about 20% by weight of a metal oxide, is contemplated wherein weight percent is with respect to the total weight of the polymer blend.

In other aspect an article comprising a polymer blend of a) about 50 to about 99% by weight of a polysulfone, poly(ether sulfone), poly(phenylene ether sulfone)s or mixture thereof;

b) about 0.1 to about 10% by weight of a silicone copolymer;

c) about 1 to about 50% by weight of a resorcinol based polyarylate resin containing greater than or equal to about 50 mole % resorcinol derived linkages;

d) 0 to about 20% by weight of a metal oxide; and

e) 0 to about 2% by weight of a phosphorus containing stabilizer, is contemplated.

B. High Tg Blends of: a PEI, PI, PEIS, and Mixtures Thereof; a Silicone Copolymer; and, a Resorcinol Based Aryl Polyester Resin.

Combinations of silicone copolymers, for instance silicone polyetherimide copolymers or silicone polycarbonate copolymers, with high glass transition temperature (Tg) polyimide (PI), polyetherimide (PEI) or polyetherimide sulfone (PEIS) resins, and resorcinol based polyarylate have surprisingly low heat release values and improved solvent resistance.

The resorcinol derived aryl polyesters can also be a copolymer containing non-resorcinol based linkages, for instance a resorcinol—bisphenol-A copolyester carbonate. For best effect, resorcinol ester content (REC) should be greater than about 50 mole % of the polymer linkages being derived from resorcinol. Higher REC may be preferred. In some instances REC of greater than 75 mole %, or even as high as 90 or 100 mole % resorcinol derived linkages may be desired.

The amount of resorcinol ester containing polymer used in the flame retardant blend can vary widely using any effective amount to reduce heat release, increase time to peak heat release or to improve solvent resistance. In some instances resorcinol ester containing polymer can be about 1 wt % to about 80 wt % of the polymer blend. Some compositions of note will have 10-50% resorcinol based polyester. In other instances blends of polyetherimide or polyetherimide sulfone with high REC copolymers will have a single glass transition temperature (Tg) of about 150 to about 210° C.

The resorcinol based polyarylate resin should contain greater than or equal to about 50 mole % of units derived from the reaction product of resorcinol, or functionalized resorcinol, with an aryl dicarboxylic acid or dicarboxylic acid derivatives suitable for the formation of aryl ester linkages, for example, carboxylic acid halides, carboxylic acid esters and carboxylic acid salts.

The resorcinol based polyarylates which can be used according to the present invention are further detailed herein for other polymer blends.

Copolyestercarbonates with at least one carbonate linkage between a thermally stable resorcinol arylate block and an organic carbonate block are typically prepared from resorcinol arylate-containing oligomers prepared by various embodiments of the invention and containing in one embodiment at least one and in another embodiment at least two hydroxy-terminal sites. Said oligomers typically have weight average molecular weight in one embodiment of about 10,000 to about 40,000, and in another embodiment of about 15,000 to about 30,000. Thermally stable copolyestercarbonates may be prepared by reacting said resorcinol arylate-containing oligomers with phosgene, at least one chain-stopper, and at least one dihydroxy-substituted aromatic hydrocarbon in the presence of a catalyst such as a tertiary amine.

In one instance a polymer blend with improved flame retardance comprises a resin selected from the group consisting of polyimides, polyetherimides, polyetherimide sulfones, and mixtures thereof; a silicone copolymer and a resorcinol based aryl polyester resin wherein greater than or equal to 50 mole % of the aryl polyester linkages are aryl ester linkages derived from resorcinol. The term “polymer linkage” or “a polymer linkage” is defined as the reaction product of at least two monomers that form the polymer.

In some instances polyimides, polyetherimides, polyetherimide sulfones and mixtures thereof, will have a hydrogen atom to carbon atom ratio (H/C) of less than or equal to about 0.85 are of note. Polymers with higher carbon content relative to hydrogen content, that is a low ratio of hydrogen to carbon atoms, often show improved FR performance. These polymers have lower fuel value and may give off less energy when burned. They may also resist burning through a tendency to form an insulating char layer between the polymeric fuel and the source of ignition. Independent of any specific mechanism or mode of action it has been observed that such polymers, with a low H/C ratio, have superior flame resistance. In some instances the H/C ratio can be less than 0.85. In other instances a H/C ratio of greater than about 0.4 is preferred in order to give polymeric structures with sufficient flexible linkages to achieve melt processability. The H/C ratio of a given polymer or copolymer can be determined from its chemical structure by a count of carbon and hydrogen atoms independent of any other atoms present in the chemical repeat unit.

In some cases the flame retardant polymer blends, and articles made from them, will have 2 minute heat release of less than about 65 kW-min/m². In other instances the peak heat release will be less than about 65 kW/m². A time to peak heat release of more than about 2 minute is also a beneficial aspect of certain compositions and articles made from them. In other instances a time to peak heat release time of greater than about 4 minutes may be achieved.

In some compositions the blend of polyimides, polyetherimides, polyetherimide sulfones or mixtures thereof with silicone copolymer and aryl polyester resin containing greater than or equal to about 50 mole % resorcinol derived linkages will be transparent. In one embodiment, the blend has a percent transmittance greater than about 50% as measured by ASTM method D1003 at a thickness of 2 millimeters. In other instances the percent haze of these transparent compositions, as measured by ASTM method D1003, will be less than about 25%. In other embodiments the percent transmittance will be greater than about 60% and the percent haze less than about 20%. In still other instances the composition and article made from it will have a transmittance of greater than about 50% and a haze value below about 25% with a peak heat release of less than or equal to 50 kW/m².

In the flame retardant blends the polyimides, polyetherimides, polyetherimide sulfones or mixtures thereof may be present in amounts of about 1 to about 99 weight percent, based on the total weight of the composition. Within this range, the amount of the polyimides, polyetherimides, polyetherimide sulfones or mixtures thereof may be greater than or equal to about 20, more specifically greater than or equal to about 50, or, even more specifically, greater than or equal to about 70 weight percent.

In another embodiment a composition comprises a flame retardant polymer blend of:

a) about 1 to about 99% by weight of a polyetherimide, polyetherimide sulfone and mixtures thereof,

b) about 99 to about 1% by weight of an aryl polyester resin containing greater than or equal to about 50 mole % resorcinol derived linkages,

c) about 0.1 to about 30% by weight of silicone copolymer d) about 0 to about 20% by weight of a metal oxide,

wherein the weight percents are with respect to the total weight of the composition.

In other aspect a composition comprises a flame retardant polymer blend of;

a) about 50 to about 99% by weight of a polyetherimide or polyetherimide sulfone resin,

b) about 1 to about 50% by weight of a resorcinol based polyarylate containing greater than or equal to about 50 mole % resorcinol derived linkages,

c) about 0.1 to about 10% by weight of silicone copolymer d) about 0 to about 20% by weight of a metal oxide, and

e) 0 to about 2% by weight of a phosphorus containing stabilizer, is contemplated.

Polyimides have the general formula (XX) 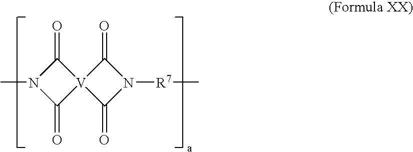
wherein a is more than 1, typically about 10 to about 1000 or more, or, more specifically about 10 to about 500; and wherein V is a tetravalent linker without limitation, as long as the linker does not impede synthesis or use of the polyimide. Suitable linkers include but are not limited to: (a) substituted or unsubstituted, saturated, unsaturated or aromatic monocyclic and polycyclic groups having about 5 to about 50 carbon atoms, (b) substituted or unsubstituted, linear or branched, saturated or unsaturated alkyl groups having 1 to about 30 carbon atoms; or combinations thereof. Preferred linkers include but are not limited to tetravalent aromatic radicals of formula (XXI), such as 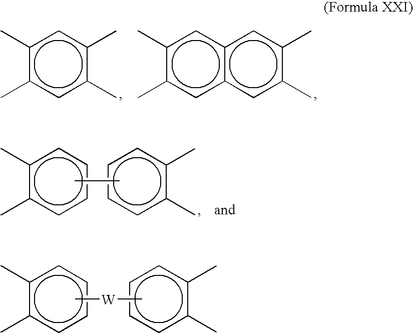
wherein W is a divalent group selected from the group consisting of —O—, —S—, —C(O)—, SO₂—, —SO—, —C_{y}H_{2y}— (y being an integer having a value of 1 to about 8), and fluoronated derivatives thereof, including perfluoroalkylene groups, or a group of the formula —O-Z-O— wherein the divalent bonds of the —W— or the —O-Z-O— group are in the 3,3′, 3,4′, 4,3′, or the 4,4′ positions, and wherein Z is defined as above. Z may comprise exemplary divalent radicals of formula (XXII).

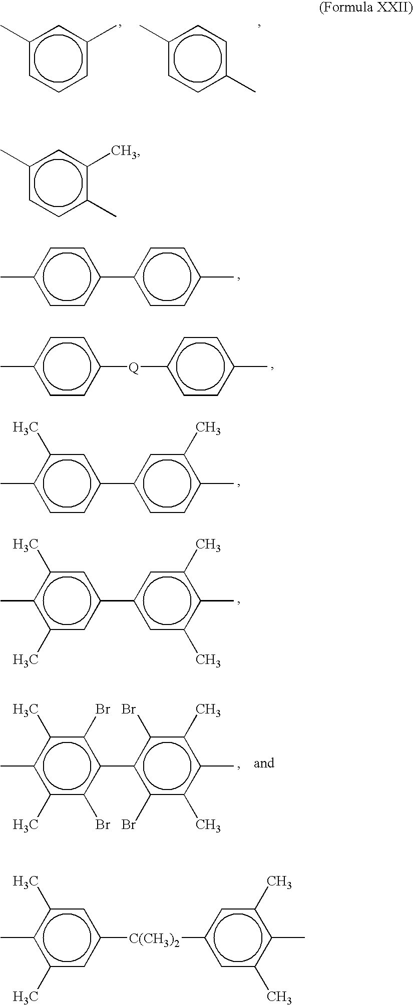

R⁷ in formula (XX) includes but is not limited to substituted or unsubstituted divalent organic radicals such as: (a) aromatic hydrocarbon radicals having about 6 to about 24 carbon atoms and halogenated derivatives thereof; (b) straight or branched chain alkylene radicals having about 2 to about 20 carbon atoms; (c) cycloalkylene radicals having about 3 to about 24 carbon atoms, or (d) divalent radicals of the general formula (VI) 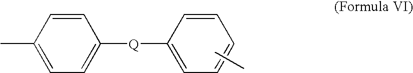
wherein Q is defined as above.

Some classes of polyimides include polyamidimides, polyetherimide sulfones and polyetherimides, particularly those polyetherimides known in the art which are melt processable, such as those whose preparation and properties are described in U.S. Pat. Nos. 3,803,085 and 3,905,942.

Polyetherimide resins may comprise more than 1, typically about 10 to about 1000 or more, or, more specifically, about 10 to about 500 structural units, of the formula (XXIII) 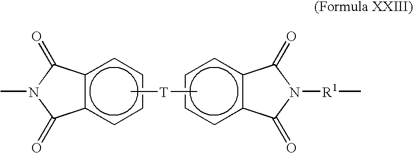
wherein T is —O— or a group of the formula —O-Z-O— wherein the divalent bonds of the —O— or the —O-Z-O— group are in the 3,3′, 3,4′, 4,3′, or the 4,4′ positions, and wherein Z is defined above. In one embodiment, the polyimide, polyetherimide or polyetherimide sulfone may be a copolymer. Mixtures of the polyimide, polyetherimide or polyetherimide sulfone may also be employed.

The polyetherimide can be prepared by any of the methods well known to those skilled in the art, including the reaction of an aromatic bis(ether anhydride) of the formula (XVIII) 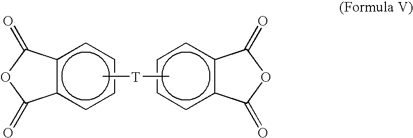
with an organic diamine of the formula (VII)
H₂N—R¹—NH₂ (Formula VII)
wherein T and R¹ are defined as described above.

Examples of specific aromatic bis anhydrides and organic diamines are disclosed, for example, in U.S. Pat. Nos. 3,972,902 and 4,455,410. Illustrative examples of aromatic bis anhydrides include:
3,3-bis[4-(3,4-dicarboxyphenoxy)phenyl]propane dianhydride;
4,4′-bis(3,4-dicarboxyphenoxy)diphenyl ether dianhydride;
4,4′-bis(3,4-dicarboxyphenoxy)diphenyl sulfide dianhydride;
4,4′-bis(3,4-dicarboxyphenoxy)benzophenone dianhydride;
4,4′-bis(3,4-dicarboxyphenoxy)diphenyl sulfone dianhydride;
2,2-bis[4-(2,3-dicarboxyphenoxy)phenyl]propane dianhydride;
4,4′-bis(2,3-dicarboxyphenoxy)diphenyl ether dianhydride;
4,4′-bis(2,3-dicarboxyphenoxy)diphenyl sulfide dianhydride;
4,4′-bis(2,3-dicarboxyphenoxy)benzophenone dianhydride;
4,4′-bis(2,3-dicarboxyphenoxy)diphenyl sulfone dianhydride;
4-(2,3-dicarboxyphenoxy)-4′-(3,4-dicarboxyphenoxy)diphenyl-2,2-propane dianhydride;
4-(2,3-dicarboxyphenoxy)-4′-(3,4-dicarboxyphenoxy)diphenyl ether dianhydride;
4-(2,3-dicarboxyphenoxy)-4′-(3,4-dicarboxyphenoxy)diphenyl sulfide dianhydride;
4-(2,3-dicarboxyphenoxy)-4′-(3,4-dicarboxyphenoxy)benzophenone dianhydride; and, 4-(2,3-dicarboxyphenoxy)-4′-(3,4-dicarboxyphenoxy)diphenyl sulfone dianhydride, as well as various mixtures thereof.

Another class of aromatic bis(ether anhydride)s included by formula (XVIII) above includes, but is not limited to, compounds wherein T is of the formula (XXIV) 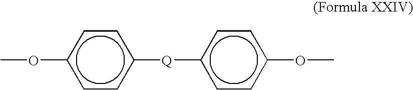
and the ether linkages, for example, are preferably in the 3,3′, 3,4′, 4,3′, or 4,4′ positions, and mixtures thereof, and where Q is as defined above.

Any diamino compound may be employed. Examples of suitable compounds are ethylenediamine, propylenediamine, trimethylenediamine, diethylenetriamine, triethylenetertramine, hexamethylenediamine, heptamethylenediamine, octamethylenediamine, nonamethylenediamine, decamethylenediamine, 1,12-dodecanediamine, 1,18-octadecanediamine, 3-methylheptamethylenediamine, 4,4-dimethylheptamethylenediamine, 4-methylnonamethylenediamine, 5-methylnonamethylenediamine, 2,5-dimethylhexamethylenediamine, 2,5-dimethylheptamethylenediamine, 2,2-dimethylpropylenediamine, N-methyl-bis(3-aminopropyl)amine, 3-methoxyhexamethylenediamine, 1,2-bis(3-aminopropoxy)ethane, bis(3-aminopropyl)sulfide, 1,4-cyclohexanediamine, bis-(4-aminocyclohexyl)methane, m-phenylenediamine, p-phenylenediamine, 2,4-diaminotoluene, 2,6-diaminotoluene, m-xylylenediamine, p-xylylenediamine, 2-methyl-4,6-diethyl-1,3-phenylene-diamine, 5-methyl-4,6-diethyl-1,3-phenylene-diamine, benzidine, 3,3′-dimethylbenzidine, 3,3′-dimethoxybenzidine, 1,5-diaminonaphthalene, bis(4-aminophenyl)methane, bis(2-chloro-4-amino-3,5-diethylphenyl)methane, bis(4-aminophenyl)propane, 2,4-bis(p-amino-t-butyl)toluene, bis(p-amino-t-butylphenyl)ether, bis(p-methyl-o-aminophenyl)benzene, bis(p-methyl-o-aminopentyl)benzene, 1,3-diamino-4-isopropylbenzene, bis(4-aminophenyl)sulfide, bis(4-aminophenyl)sulfone, and bis(4-aminophenyl)ether. Mixtures of these compounds may also be used. The preferred diamino compounds are aromatic diamines, especially m- and p-phenylenediamine, sulfonyl dianiline and mixtures thereof.

In one embodiment, the polyetherimide resin comprises structural units according to formula (XVII) wherein each R is independently p-phenylene or m-phenylene or a mixture thereof and T is a divalent radical of the formula (XXV)

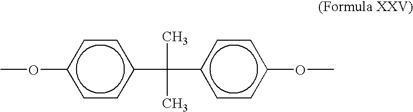

Included among the many methods of making the polyimides, particularly polyetherimides, are those disclosed in U.S. Pat. Nos. 3,847,867, 3,852,242, 3,803,085, 3905,942, 3,983,093, and 4,443,591. These patents mentioned for the purpose of teaching, by way of illustration, general and specific methods for preparing polyimides.

Polyimides, polyetherimides and polyetherimide sulfones may have a melt index of about 0.1 to about 10 grams per minute (g/min), as measured by American Society for Testing Materials (ASTM) D1238 at 340 to about 370° C., using a 6.6 kilogram (kg) weight. In a one embodiment, the polyetherimide resin has a weight average molecular weight (Mw) of about 10,000 to about 150,000 grams per mole (g/mole), as measured by gel permeation chromatography, using a polystyrene standard. In another embodiment the polyetherimide has Mw of 20,000 to 60,000. Such polyetherimide resins typically have an intrinsic viscosity greater than about 0.2 deciliters per gram (dl/g), or, more specifically, about 0.35 to about 0.7 dl/g as measured in m-cresol at 25° C. Examples of some polyetherimides useful in blends described herein are listed in ASTM D5205 “Standard Classification System for Polyetherimide (PEI) Materials”.

The block length of the siloxane segment of the copolymer may be of any effective length. In some examples it may be of 2 to −70 siloxane repeating units. In other instances the siloxane block length may be about 5 to about 30 repeat units. In many instances dimethyl siloxanes may be used.

Siloxane polyetherimide copolymers are a specific embodiment of the siloxane copolymer that may be used. Examples of such siloxane polyetherimides are shown in U.S. Pat. Nos. 4,404,350, 4,808,686 and 4,690,997. In one instance polyetherimide siloxanes can be prepared in a manner similar to that used for polyetherimides, except that a portion, or all, of the organic diamine reactant is replaced by an amine-terminated organo siloxane, for example of the formula XXII wherein g is an integer having a value of 1 to about 50, in some other instances g may be about 5 to about 30 and R′ is an aryl, alkyl or aryl alkyl group of having about 2 to about 20 carbon atoms.

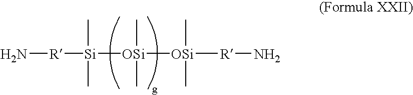

Some polyetherimde siloxanes may be formed by reaction of an organic diamine, or mixture of diamines, of formula XIX and the amine-terminated organo siloxane of formula XXII and one or more dianhydrides of formula XVIII. The diamino components may be physically mixed prior to reaction with the bis-anhydride(s), thus forming a substantially random copolymer. Alternatively block or alternating copolymers may be formed by selective reaction of XIX and XXII with dianhydrides to make polyimide blocks that are subsequently reacted together. In another instance the siloxane used to prepare the polyetherimde copolymer may have anhydride rather than amine functional end groups, for example as described in U.S. Pat. No. 4,404,350.

In one instance the siloxane polyetherimide copolymer can be of formula XXIII wherein T, R′ and g are described as above, n has a value of about 5 to about 100 and Ar is an aryl or alkyl aryl group having 6 to about 36 carbons.

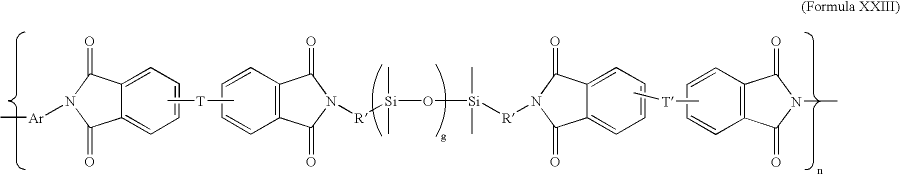

In some siloxane polyetherimides the diamine component of the siloxane polyetherimide copolymers may contain about 20 mole % to about 50 mole % of the amine-terminated organo siloxane of formula XXII and about 50 to about 80 mole % of the organic diamine of formula XIX. In some siloxane copolymers, the siloxane component contains about 25 to about 40 mole % of the amine or anhydride terminated organo siloxane.

C. High Tg Phase Separated Polymer Blends.

Also disclosed herein are phase separated polymer blends comprising a mixture of: a) a poly aryl ether ketone (PAEK) selected from the group comprising: polyaryl ether ketones, polyaryl ketones, polyether ketones and polyether ether ketones; and combinations thereof with, b) a polyetherimide sulfone (PEIS) having greater than or equal to 50 mole % of the linkages containing an aryl sulfone group.

Phase separated means that the PAEK and the PEIS exist in admixture as separate chemical entities that can be distinguished, using standard analytical techniques, for example such as microscopy, differential scanning calorimetry or dynamic mechanical analysis, to show a least two distinct polymeric phases one of which comprises PAEK resin and one of which comprises PEIS resin. In some instances each phase will contain greater than about 80 wt % of the respective resin. In other instances the blends will form separate distinct domains about 0.1 to about 50 micrometers in size, in others cases the domains will be about 0.1 to about 20 micrometers. Domain size refers to the longest linear dimension as shown by microscopy. The phase separated blends may be completely immiscible or may show partial miscibility but must behave such that, at least in the solid state, the blend shows two or more distinct polymeric phases.

The ratio of PAEK to PEIS can be any that results in a blend that has improved properties i.e. better or worse depending on the end use application, than either resin alone. The ratio, in parts by weight, may be 1:99 to 99:1, depending on the end use application, and the desired property to be improved. The range of ratios can also be 15:85 to 85:15 or even 25:75 to 75:25. Depending on the application, the ratio may also be 40:60 to 60:40. The skilled artisan will appreciate that changing the ratios of the PAEK to PEIS can fall to any real number ratio within the recited ranges depending on the desired result.

The properties of the final blend, which can be adjusted by changing the ratios of ingredients, include heat distortion temperature and load bearing capability. For example, in one embodiment the polyetherimide sulfone resin can be present in any amount effective to change, i.e. improve by increasing, the load bearing capability of the PAEK blends over the individual components themselves. In some instances the PAEK can be present in an amount of about 30 to about 70 wt % of the entire mixture while the amount of the PEIS may be about 70 to about 30 wt % wherein the weight percents are with respect to the combined weight of the PAEK and the PEIS.

In some embodiments the phase separated polymer blend will have a heat distortion temperature (HDT) measured using ASTM method D5418, on a 3.2 mm bar at 0.46 Mpa (66 psi) of greater than or equal to about 170° C. In other instances the HDT at 0.46 MPA (66 psi) will be greater than or equal to 200° C. In still other instances, load bearing capability of the PAEK-PEIS will be shown in a Vicat temperature, as measured by ASTM method D1525 at 50 newtons (N) of greater than or equal to about 200° C.

In still other instances load bearing capability of the phase separated polymer blend will be shown by a flexural modulus of greater than or equal to about 200 megapascals (MPa) as measured on a 3.2 mm bar, for example as measured by ASTM method D5418, at 200° C.

The phase separated polymer blends may be made by mixing in the molten state, an amount of PAEK; with and amount of the PEIS The two components may be mixed by any method known to the skilled artisan that will result in a phase separated blend. Such methods include extrusion, sintering and etc.

As used herein the term polyaryl ether ketones (PAEK) comprises several polymer types containing aromatic rings, usually phenyl rings, linked primarily by ketone and ether groups in different sequences. Examples of PAEK resins include polyether ketones (PEK), polyether ether ketones (PEEK), polyether ketone ether ketone ketones (PEKEKK) and polyether ketone ketones (PEKK) and copolymers containing such groups as well as blends thereof. The PAEK polymers may comprise monomer units containing an aromatic ring, usually a phenyl ring, a keto group and an ether group in any sequence. Low levels, for example less than 10 mole %, of addition linking groups may be present as long as they do not fundamentally alter the properties of the PAEK resin

For example, several polyaryl ether ketones which are highly crystalline, with melting points above 300° C., can be used in the phase separated blends. Examples of these crystalline polyaryl ether ketones are shown in the structures XXVI, XXVII, XXVM, XXIX, and XXX.

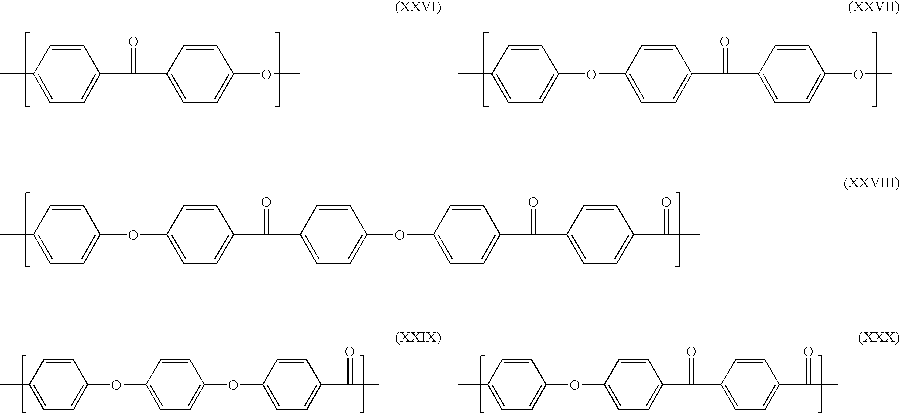

Other examples of crystalline polyaryl ether ketones which are suitable for use herein can be generically characterized as containing repeating units of the following formula (XXXI): 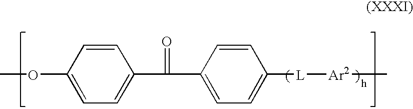
wherein Ar² is independently a divalent aromatic radical selected from phenylene, biphenylene or naphthylene, L is independently —O—, —C(O)—, —O—Ar—C(O)—, —S—, —SO₂— or a direct bond and h is an integer having a value of 0 to about 10.

The skilled artisan will know that there is a well-developed and substantial body of patent and other literature directed to formation and properties of polyaryl ether ketones. For example, some of the early work, such as U.S. Pat. No. 3,065,205, involves the electrophilic aromatic substitution (e.g., Friedel-Crafts catalyzed) reaction of aromatic diacyl halides with unsubstituted aromatic compounds such as diphenyl ether. The evolution of this class was achieved in U.S. Pat. No. 4,175,175 which shows that a broad range of resins can be formed, for example, by the nucleophilic aromatic substitution reaction of an activated aromatic dihalide and an aromatic diol or salt thereof.

One such method of preparing a poly aryl ketone comprises heating a substantially equimolar mixture of a bisphenol, often reacted as its bis-phenolate salt, and a dihalobenzoid compound or, in other cases, a halophenol compound. In other instances mixtures of these compounds may be used. For example hydroquinone can be reacted with a dihalo aryl ketone, such a dichloro benzophenone or difluoro benzophenone to form a poly aryl ether ketone. In other cases a dihydroxy aryl ketone, such as dihydroxy benzophenone can be polymerized with aryl dihalides such as dichloro benzene to form PAEK resins. In still other instances dihydroxy aryl ethers, such as dihydroxy diphenyl ether can be reacted with dihalo aryl ketones, such a difluoro benzophenone. In other variations dihydroxy compounds with no ether linkages, such as or dihydroxy biphenyl or hydroquinone may be reacted with dihalo compounds which may have both ether and ketone linkages, for instance bis-(dichloro phenyl)benzophenone. In other instances diaryl ether carboxylic acids, or carboxylic acid halides can be polymerized to form poly aryl ether ketones. Examples of such compounds are diphenylether carboxylic acid, diphenyl ether carboxylic acid chloride, phenoxy-phenoxy benzoic acid, or mixtures thereof. In still other instances dicarboxylic acids or dicarboxylic acid halides can be condensed with diaryl ethers, for instance iso or tere phthaloyl chlorides (or mixtures thereof) can be reacted with diphenyl ether, to form PAEK resins.

The process is described in, for example, U.S. Pat. No. 4,176,222. The process comprises heating in the temperature range of 100 to 400° C., (i) a substantially equimolar mixture of: (a) a bisphenol; and, (b.i) a dihalobenzenoid compound, and/or (b.ii) a halophenol, in which in the dihalobenzenoid compound or halophenol, the halogen atoms are activated by —C═O— groups ortho or para thereto, with a mixture of sodium carbonate or bicarbonate and a second alkali metal carbonate or bicarbonate, the alkali metal of said second alkali metal carbonate or bicarbonate having a higher atomic number than that of sodium, the amount of said second alkali metal carbonate or bicarbonate being such that there are 0.001 to 0.2 gram atoms of said alkali metal of higher atomic number per gram atom of sodium, the total amount of alkali metal carbonate or bicarbonate being such that there is at least one alkali metal atom for each phenol group present, and thereafter separating the polymer from the alkali metal halide.

Yet other poly aryl ether ketones may also be prepared according to the process as described in, for example, U.S. Pat. No. 4,396,755. In such processes, reactants such as: (a) a dicarboxylic acid; (b) a divalent aromatic radical and a mono aromatic dicarboxylic acid and, (c) combinations of (a) and (b), are reacted in the presence of a fluoro alkane sulfonic acid, particularly trifluoromethane sulfonic acid.

Additional polyaryl ether ketones may be prepared according to the process as described in, for example, U.S. Pat. No. 4,398,020 wherein aromatic diacyl compounds are polymerized with an aromatic compound and a mono acyl halide.

The polyaryl ether ketones may have a reduced viscosity of greater than or equal to about 0.4 to about 5.0 dl/g, as measured in concentrated sulfuric acid at 25 C. PAEK weight average molecular weight (Mw) may be about 5,000 to about 150,000 g/mole. In other instances Mw may be about 10,000 to about 80,000 g/mole.

The second resin component is a polyetherimide sulfone (PEIS) resin. As used herein the PEIS comprises structural units having the general formula (VII) wherein greater than or equal to about 50 mole % of the polymer linkages have an aryl sulfone group and 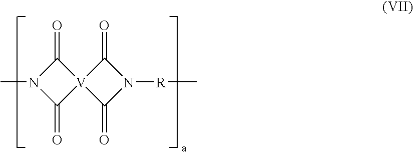
wherein a is more than 1, typically about 10 to about 1000 or more, or, more specifically, about 10 to about 500; and V is a tetravalent linker without limitation, as long as the linker does not impede synthesis or use of the polysulfone etherimide. Suitable linkers include but are not limited to: (a) substituted or unsubstituted, saturated, unsaturated or aromatic monocyclic or polycyclic groups having about 5 to about 50 carbon atoms; (b) substituted or unsubstituted, linear or branched, saturated or unsaturated alkyl groups having 1 to about 30 carbon atoms; or (c) combinations thereof. Preferred linkers include but are not limited to tetravalent aromatic radicals of formula (VIII), such as, 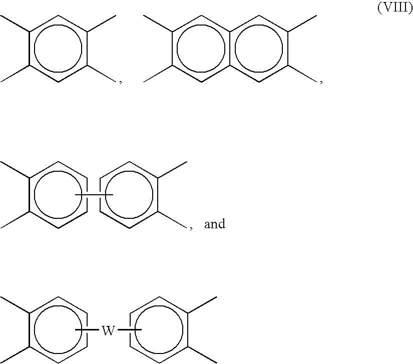
wherein W is in some embodiments a divalent group selected from the group consisting of —SO₂—, —O—, —S—, —C(O)—, C_{y}H_{2y}— (y being an integer having a value of 1 to 5), and halogenated derivatives thereof, including perfluoroalkylene groups, or a group of the formula —O-D-O—. The group D may comprise the residue of bisphenol compounds. For example, D may be any of the molecules shown in formula DC.

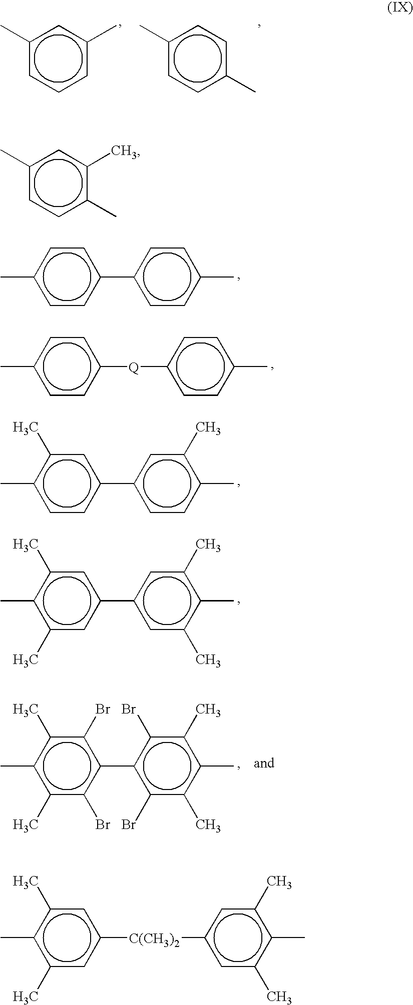

The divalent bonds of the —W— or the —O-D-O— group may be in the 3,3′, 3,4′, 4,3′, or the 4,4′ positions. Mixtures of the aforesaid compounds may also be used. Groups free of benzylic protons are often preferred for superior melt stability. Groups where W is —SO₂— are of specific note as they are one method of introducing aryl sulfone linkages into the polysulfone etherimide resins.

As used herein the term “polymer linkage” or “a polymer linkage” is defined as the reaction product of at least two monomers which form the polymer, wherein at least one of the monomers is a dianhydride, or chemical equivalent, and wherein the second monomer is at least one diamine, or chemical equivalent. The polymer is comprised on 100 mole % of such linkages. A polymer which has 50 mole % aryl sulfone linkages, for example, will have half of its linkages (on a molar basis) comprising dianhydride or diamine derived linkages with at least one aryl sulfone group.

Suitable dihydroxy-substituted aromatic hydrocarbons used as precursors to the —O-D-O— group also include those of the formula (X): 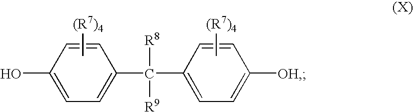
where each R⁷ is independently hydrogen, chlorine, bromine, alkoxy, aryloxy or a C₁₋₃₀ monovalent hydrocarbon or hydrocarbonoxy group, and R⁸ and R⁹ are independently hydrogen, aryl, alkyl fluoro groups or C₁₋₃₀ hydrocarbon groups.

Dihydroxy-substituted aromatic hydrocarbons that may be used as precursors to the —O-D-O— group include those disclosed by name or formula in U.S. Pat. Nos. 2,991,273, 2,999,835, 3,028,365, 3,148,172, 3,153,008, 3,271,367, 3,271,368, and 4,217,438. Specific examples of dihydroxy-substituted aromatic hydrocarbons which can be used include, but are not limited to, bis(4-hydroxyphenyl)sulfone, bis(4-hydroxyphenyl)sulfide, bis(4-hydroxyphenyl)ether, bis(4-hydroxyphenyl)sulfoxide, 1,4-dihydroxybenzene, 4,4′-oxydiphenol, 2,2-bis(4-hydroxyphenyl)hexafluoropropane, 4,4′-(3,3,5-trimethylcyclohexylidene)diphenol; 4,4′-bis(3,5-dimethyl)diphenol, 1,1-bis(4-hydroxy-3-methylphenyl)cyclohexane; 4,4-bis(4-hydroxyphenyl)heptane; 2,4′-dihydroxydiphenylmethane; bis(2-hydroxyphenyl)methane; bis(4-hydroxyphenyl)methane; bis(4-hydroxy-5-nitrophenyl)methane; bis(4-hydroxy-2,6-dimethyl-3-methoxyphenyl)methane; 1,1-bis(4-hydroxyphenyl)ethane; 1,2-bis(4-hydroxyphenyl)ethane; 1,1-bis(4-hydroxy-2-chlorophenyl)ethane; 2,2-bis(3-phenyl-4-hydroxyphenyl)propane; 2,2-bis(4-hydroxy-3-methylphenyl)propane; 2,2-bis(4-hydroxy-3-ethylphenyl)propane; 2,2-bis(4-hydroxy-3-isopropylphenyl)propane; 2,2-bis(4-hydroxy-3,5-dimethylphenyl)propane; 3,5,3′,5′-tetrachloro-4,4′-dihydroxyphenyl)propane; bis(4-hydroxyphenyl)cyclohexylmethane; 2,2-bis(4-hydroxyphenyl)-1-phenylpropane; 2,4′-dihydroxyphenyl sulfone; dihydroxy naphthalene; 2,6-dihydroxy naphthalene; hydroquinone; resorcinol; C₁₋₃ alkyl-substituted resorcinols; methyl resorcinol, 1,4-dihydroxy-3-methylbenzene; 2,2-bis(4-hydroxyphenyl)butane; 2,2-bis(4-hydroxyphenyl)-2-methylbutane; 1,1-bis(4-hydroxyphenyl)cyclohexane; 4,4′-dihydroxydiphenyl; 2-(3-methyl-4-hydroxyphenyl-2-(4-hydroxyphenyl)propane; 2-(3,5-dimethyl-4-hydroxyphenyl)-2-(4-hydroxyphenyl)propane; 2-(3-methyl-4-hydroxyphenyl)-2-(3,5-dimethyl-4-hydroxyphenyl)propane; bis(3,5-dimethylphenyl-4-hydroxyphenyl)methane; 1,1-bis(3,5-dimethylphenyl-4-hydroxyphenyl)ethane; 2,2-bis(3,5-dimethylphenyl-4-hydroxyphenyl)propane; 2,4-bis(3,5-dimethylphenyl-4-hydroxyphenyl)-2-methylbutane; 3,3-bis(3,5-dimethylphenyl-4-hydroxyphenyl)pentane; 1,1-bis(3,5-dimethylphenyl-4-hydroxyphenyl)cyclopentane; 1,1-bis(3,5-dimethylphenyl-4-hydroxyphenyl)cyclohexane; bis(3,5-dimethyl-4-hydroxyphenyl)sulfoxide, bis(3,5-dimethyl-4-hydroxyphenyl)sulfone and bis(3,5-dimethylphenyl-4-hydroxyphenyl)sulfide. Mixtures comprising any of the foregoing dihydroxy-substituted aromatic hydrocarbons may also be employed.

In a particular embodiment the dihydroxy-substituted aromatic hydrocarbon comprising bisphenols with sulfone linkages are of note as this is another route to introducing aryl sulfone linkages into the polysulfone etherimide resin. In other instances bisphenol compounds free of benzylic protons may be preferred to make polyetherimide sulfones with superior melt stability.

In Formula (VU) the R group is the residue of a diamino compound, or chemical equivalent, that includes but is not limited to substituted or unsubstituted divalent organic radicals such as: (a) aromatic hydrocarbon radicals having about 6 to about 24 carbon atoms and halogenated derivatives thereof; (b) straight or branched chain alkylene radicals having about 2 to about 20 carbon atoms; (c) cycloalkylene radicals having about 3 to about 24 carbon atoms, or (d) divalent radicals of the general formula (XI) 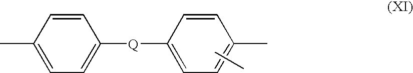
wherein Q includes but is not limited to a divalent group selected from the group consisting of —SO₂—, —O—, —S—, —C(O)—, C_{y}H_{2y}— (y being an integer having a value of 1 to about 5), and halogenated derivatives thereof, including perfluoroalkylene groups. In particular embodiments R is essentially free of benzylic hydrogens. The presence of benzylic protons can be deduced from the chemical structure.

In some particular embodiments suitable aromatic diamines comprise meta-phenylenediamine; para-phenylenediamine; mixtures of meta- and para-phenylenediamine; isomeric 2-methyl- and 5-methyl-4,6-diethyl-1,3-phenylene-diamines or their mixtures; bis(4-aminophenyl)-2,2-propane; bis(2-chloro-4-amino-3,5-diethylphenyl)methane, 4,4′-diaminodiphenyl, 3,4′-diaminodiphenyl, 4,4′-diaminodiphenyl ether (sometimes referred to as 4,4′-oxydianiline); 3,4′-diaminodiphenyl ether, 3,3′-diaminodiphenyl ether, 4,4′-diaminodiphenyl sulfone, 3,4′-diaminodiphenyl sulfone, 3,3′-diaminodiphenyl sulfone, 4,4′-diaminodiphenyl sulfide; 3,4′-diaminodiphenyl sulfide; 4,4′-diaminodiphenyl ketone, 3,4′-diaminodiphenyl ketone, 4,4′-diaminodiphenylmethane (commonly named 4,4′-methylenedianiline); 4,4′-bis(4-aminophenoxy)biphenyl, 4,4′-bis(3-aminophenoxy)biphenyl, 1,5-diaminonaphthalene; 3,3-dimethylbenzidine; 3,3-dimethoxybenzidine; benzidine; m-xylylenediamine; bis(aminophenoxy)fluorene, bis(aminophenoxy)benzene, 1,3-bis(3-aminophenoxy)benzene, 1,3-bis(4-aminophenoxy)benzene, 1,4-bis(4-aminophenoxy)benzene, bis(aminophenoxy)phenyl sulfone, bis(4-(4-aminophenoxy)phenyl)sulfone, bis(4-(3-aminophenoxy)phenyl)sulfone, diaminobenzanilide, 3,3′-diaminobenzophenone, 4,4′-diaminobenzophenone, 2,2′-bis(4-(4-aminophenoxy)phenyl)propane, 2,2-bis[4-(4-aminophenoxy)phenyl]hexafluoropropane, 4,4′-bis(aminophenyl)hexafluoropropane, 1,3-diamino-4-isopropylbenzene; 1,2-bis(3-aminophenoxy)ethane; 2,4-bis(beta-amino-t-butyl)toluene; bis(p-beta-methyl-o-aminophenyl)benzene; bis(p-beta-amino-t-butylphenyl)ether and 2,4-toluenediamine. Mixtures of two or more diamines may also be employed. Diamino diphenyl sulfone (DDS), bis(aminophenoxy phenyl)sulfones (BAPS) and mixtures thereof are preferred aromatic diamines.

Thermoplastic polysulfone etherimides described herein can be derived from reactants comprising one or more aromatic diamines or their chemically equivalent derivatives and one or more aromatic tetracarboxylic acid cyclic dianhydrides (sometimes referred to hereinafter as aromatic dianhydrides), aromatic tetracarboxylic acids, or their derivatives capable of forming cyclic anhydrides or the thermal/catalytic rearrangement of preformed polyisoimides. In addition, at least a portion of one or the other of, or at least a portion of each of, the reactants comprising aromatic diamines and aromatic dianhydrides comprises an aryl sulfone linkage such that at least 50 mole % of the resultant polymer linkages contain at least one aryl sulfone group. In a particular embodiment all of one or the other of, or, each of, the reactants comprising aromatic diamines and aromatic dianhydrides having at least one sulfone linkage. The reactants polymerize to form polymers comprising cyclic imide linkages and sulfone linkages.

Illustrative examples of aromatic dianhydrides include:
4,4′-bis(3,4-dicarboxyphenoxy)diphenyl sulfone dianhydride;
4,4′-bis(2,3-dicarboxyphenoxy)diphenyl sulfone dianhydride;
4-(2,3-dicarboxyphenoxy)-4′-(3,4-dicarboxyphenoxy)diphenyl sulfone dianhydride, and mixtures thereof.

Other useful aromatic dianhydrides comprise:
2,2-bis(4-(3,4-dicarboxyphenoxy)phenyl)propane dianhydride;
4,4′-bis(3,4-dicarboxyphenoxy)diphenyl ether dianhydride;
4,4′-bis(3,4-dicarboxyphenoxy)diphenyl sulfide dianhydride;
4,4′-bis(3,4-dicarboxyphenoxy)benzophenone dianhydride;
2,2-bis([4-(2,3-dicarboxyphenoxy)phenyl]propane dianhydride;
4,4′-bis(2,3-dicarboxyphenoxy)diphenyl ether dianhydride;
4,4′-bis(2,3-dicarboxyphenoxy)diphenyl sulfide dianhydride;
4,4′-bis(2,3-dicarboxyphenoxy)benzophenone dianhydride;
2-[4-(3,4-dicarboxyphenoxy)phenyl]-2-[4-(2,3-dicarboxyphenoxy)phenyl]propane dianhydride;
4-(2,3-dicarboxyphenoxy)-4′-(3,4-dicarboxyphenoxy)diphenyl ether dianhydride;
4-(2,3-dicarboxyphenoxy)-4′-(3,4-dicarboxyphenoxy)diphenyl sulfide dianhydride;
4-(2,3-dicarboxyphenoxy)-4′-(3,4-dicarboxyphenoxy)benzophenone dianhydride;
1,4,5,8-naphthalenetetracarboxylic acid dianhydride;
3,4,3′,4′-benzophenonetetracarboxylic acid dianhydride;
2,3,3′,4′-benzophenonetetracarboxylic acid dianhydride;
3,4,3′,4′-oxydiphthalic anhydride; 2,3,3′,4′-oxydiphthalic anhydride;
3,3′,4,4′-biphenyltetracarboxylic acid dianhydride;
2,3,3′,4′-biphenyltetracarboxylic acid dianhydride;
2,3,2′,3′-biphenyltetracarboxylic acid dianhydride; pyromellitic dianhydride;
3,4,3′,4′-diphenylsulfonetetracarboxylic acid dianhydride;
2,3,3′,4′-diphenylsulfonetetracarboxylic acid dianhydride;
1,4-bis(3,4-dicarboxyphenoxy)benzene dianhydride; and,
2,2-bis(3,4-dicarboxyphenyl)hexafluoropropane dianhydride. Polysulfone etherimides with structural units derived from mixtures comprising two or more dianhydrides are also contemplated.

In other instances, the polysulfone etherimides have greater than or equal to about 50 mole % imide linkages derived from an aromatic ether anhydride that is an oxydiphthalic anhydride, in an alternative embodiment, about 60 mole % to about 100 mole % oxydiphthalic anhydride derived imide linkages. In an alternative embodiment, about 70 mole % to about 99 mole % of the imide linkages are derived from oxydiphthalic anhydride or chemical equivalent.

The term “oxydiphthalic anhydride” means the oxydiphthalic anhydride of the formula (XII) 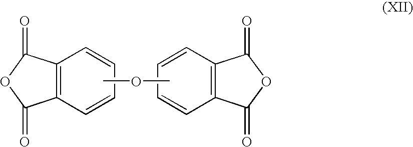
and derivatives thereof as further defined below.

The oxydiphthalic anhydrides of formula (XII) includes 4,4′-oxybisphthalic anhydride, 3,4′-oxybisphthalic anhydride, 3,3′-oxybisphthalic anhydride, and any mixtures thereof. For example, the polysulfone etherimide containing greater than or equal to about 50 mole % imide linkages derived from oxydiphthalic anhydride may be derived from 4,4′-oxybisphthalic anhydride structural units of formula (XIII)

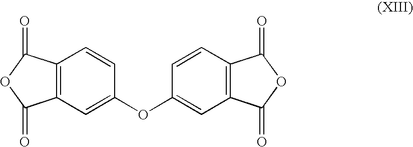

As mentioned above, derivatives of oxydiphthalic anhydrides may be employed to make polysulfone etherimides. Examples of a derivatized anhydride group which can function as a chemical equivalent for the oxydiphthalic anhydride in imide forming reactions, includes oxydiphthalic anhydride derivatives of the formula (XIV) 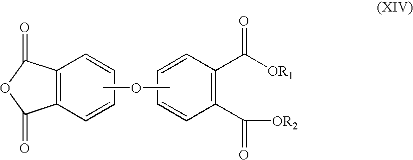
wherein R₁ and R₂ of formula VII can be any of the following: hydrogen; an alkyl group; an aryl group. R₁ and R₂ can be the same or different to produce an oxydiphthalic anhydride acid, an oxydiphthalic anhydride ester, and an oxydiphthalic anhydride acid ester.

The polysulfone etherimides herein may include imide linkages derived from oxydiphthalic anhydride derivatives which have two derivatized anhydride groups, such as for example, where the oxy diphthalic anhydride derivative is of the formula (XV) 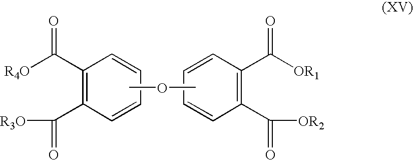
wherein R₁, R₂, R₃ and R₄ of formula (XV) can be any of the following: hydrogen; an alkyl group, an aryl group. R₁, R₂, R₃, and R₄ can be the same or different to produce an oxydiphthalic acid, an oxydiphthalic ester, and an oxydiphthalic acid ester.

Copolymers of polysulfone etherimides which include structural units derived from imidization reactions of mixtures of the oxydiphthalic anhydrides listed above having two, three, or more different dianhydrides, and a more or less equal molar amount of an organic diamine with a flexible linkage, are also contemplated. In addition, copolymers having greater than or equal to about 50 mole % imide linkages derived from oxy diphthalic anhydrides defined above, which includes derivatives thereof, and up to about 50 mole % of alternative dianhydrides distinct from oxydiphthalic anhydride are also contemplated. That is, in some instances it will be desirable to make copolymers that in addition to having greater than or equal to about 50 mole % linkages derived from oxydiphthalic anhydride, will also include imide linkages derived from aromatic dianhydrides different than oxydiphthalic anhydrides such as, for example, bisphenol A dianhydride (BPADA), disulfone dianhydride, benzophenone dianhydride, bis(carbophenoxy phenyl)hexafluoro propane dianhydride, bisphenol dianhydride, pyromellitic dianhydride (PMDA), biphenyl dianhydride, sulfur dianhydride, sulfo dianhydride and mixtures thereof.

In another embodiment, the dianhydride, as defined above, reacts with an aryl diamine that has a sulfone linkage. In one embodiment the polysulfone etherimide includes structural units that are derived from an aryl diamino sulfone of the formula (XVI)
H₂N—Ar—SO₂—Ar—NH₂ (XVI)
wherein Ar can be an aryl group species containing a single or multiple rings. Several aryl rings may be linked together, for example through ether linkages, sulfone linkages or more than one sulfone linkages. The aryl rings may also be fused.

In alternative embodiments, the amine groups of the aryl diamino sulfone can be meta or para to the sulfone linkage, for example, as in formula (XVII)

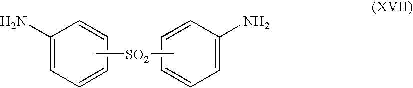

Aromatic diamines include, but are not limited to, for example, diamino diphenyl sulfone (DDS) and bis(aminophenoxy phenyl)sulfones (BAPS). The oxy diphthalic anhydrides described above may be used to form polyimide linkages by reaction with an aryl diamino sulfone to produce polysulfone etherimides.

In some embodiments the polysulfone etherimide resins can be prepared from reaction of an aromatic dianhydride monomer (or aromatic bis(ether anhydride) monomer) with an organic diamine monomer wherein the two monomers are present in essentially equimolar amounts, or wherein one monomer is present in the reaction mixture at no more than about 20% molar excess, and preferably less than about 10% molar excess in relation to the other monomer, or wherein one monomer is present in the reaction mixture at no more than about 5% molar excess. In other instances the monomers will be present in amounts differing by less than 1% molar excess.

Alkyl primary amines such as methyl amine may be used as chain stoppers. Primary monoamines may also be used to end-cap or chain-stop the polysulfone etherimide, for example, to control molecular weight. In a particular embodiment primary monoamines comprise aromatic primary monoamines, illustrative examples of which comprise aniline, chloroaniline, perfluoromethyl aniline, naphthyl amines and the like. Aromatic primary monoamines may have additional functionality bound to the aromatic ring: such as, but not limited to, aryl groups, alkyl groups, aryl-alkyl groups, sulfone groups, ester groups, amide groups, halogens, halogenated alkyl or aryl groups, alkyl ether groups, aryl ether groups, or aryl keto groups. The attached functionality should not impede the function of the aromatic primary monoamine to control polysulfone etherimide molecular weight. Suitable monoamine compounds are listed in U.S. Pat. No. 6,919,422.

Aromatic dicarboxylic acid anhydrides, that is aromatic groups comprising one cyclic anhydride group, may also be used to control molecular weight in polyimide sulfones. Illustrative examples comprise phthalic anhydride, substituted phthalic anhydrides, such as chlorophthalic anhydride, and the like. Said anhydrides may have additional functionality bound to the aromatic ring, illustrative examples of which comprise those functionalities described above for aromatic primary monoamines.

In some instances polysulfone etherimides with low levels of isoalkylidene linkages may be desirable. It is believed that in some PAEK blends the presence of isoalkylidene linkages may promote miscibility, which could reduce load bearing capability at high temperature and would be undesirable. Miscible PEEK blends with isoalkylidene containing polymer are described, for example, U.S. Pat. Nos. 5,079,309 and 5,171,796. In some instances low levels of isoalkylidene groups can mean less that 30 mole % of the polysulfone etherimide linkages will contain isoalkylidene groups, in other instances the polysulfone etherimide linkages will contain less than 20 mole % isoalkylidene groups. In still other instances less than 10 mole % isoalkylidene groups will be present in the polysulfone etherimide linkages.

Polysulfone etherimides may have a melt index of about 0.1 to about 10 grams per minute (g/min), as measured by American Society for Testing Materials (ASTM) D1238 at 340-425° C. In a one embodiment, the polysulfone etherimide resin has a weight average molecular weight (Mw) of about 10,000 to about 150,000 grams per mole (g/mole), as measured by gel permeation chromatography, using a polystyrene standard. In another embodiment the polysulfone etherimide has Mw of 20,000 to 60,000 g/mole. Examples of some polyetherimides are listed in ASTM D5205 “Standard Classification System for Polyetherimide (PEI) Materials”.

In some instances, especially where the formation of the film and fiber are desired, the composition should be essentially free of fibrous reinforcement such as glass, carbon, ceramic or metal fibers. Essentially free in some instances means less than 5 wt % of the entire composition. In other cases, the composition should have less than 1 wt % fibrous reinforcement present.

In other instances it is useful to have compositions that develop some degree of crystallinity on cooling. This may be more important in articles with high surface area such as fibers and films which will cool of quickly due to their high surface area and may not develop the full crystallinity necessary to get optimal properties. In some instances the formation of crystallinity is reflected in the crystallization temperature (Tc), which can be measured by a methods such as differential scanning calorimetry (DSC), for example, ASTM method D3418. The temperature of the maximum rate of crystallization may be measured as the Tc. In some instances, for example at a cooling rate of 80° C./min., it may be desirable to have a Tc of greater than or equal to about 240° C. In other instances, for example a slower cooling rate of 20° C./min., a crystallization temperature of greater than or equal to about 280° C. may be desired.

In some instances the composition will have at least two distinct glass transition temperatures (Tg), a first Tg from the PAEK resin, or a partially miscible PAEK blend, and a second Tg associated with the polysulfone etherimide resin, or mixture where such resin predominates. These glass transition temperatures (Tgs) can be measured by any conventional method such as DSC or dynamic mechanical analysis (DMA). In some instances the first Tg can be about 120 to about 200° C. and the second Tg can be about 240 to about 350° C. In other instances it may be useful to have an even higher second Tg, about 280 to about 350° C. In some instances, depending on the specific resins, molecular weights and composition of the blend, the Tgs may be distinct or the transitions may partially overlap.

In another embodiment the polysulfone etherimide PEAK blends will have melt viscosity of about 200 Pascal-seconds to about 10,000 Pascal-seconds (Pa-s) at 380° C. as measured by ASTM method D3835 using a capillary rheometer with a shear rate of 100 to 10000 l/sec. Resin blends having a melt viscosity of about 200 Pascal-seconds to about 10,000 Pascal-seconds at 380° C. will allow the composition to be more readily formed into articles using melt processing techniques. In other instances a lower melt viscosity of about 200 to about 5,000 Pa-s will be useful.

Another aspect of melt processing, especially at the high temperature needed for the PAEK-polysulfone etherimide compositions described herein, is that the melt viscosity of the composition not undergo excessive change during the molding or extrusion process. One method to measure melt stability is to examine the change in viscosity vs. time at a processing temperature, for example 380° C. using a parallel plate rheometer. In some instances greater than or equal to about 50% of the initial viscosity should be retained after being held at temperature for greater than or equal to about 10 minutes. In other instances the melt viscosity change should be less than about 35% of the initial value for at least about 10 minutes. The initial melt viscosity values can be measured from 1 to 5 minutes after the composition has melted and equilibrated. It is common to wait 1-5 minutes after heat is applied to the sample before measuring (recording) viscosity to ensure the sample is fully melted and equilibrated. Suitable methods for measuring melt viscosity vs. time are, for example, ASTM method D4440. Note that melt viscosity can be reported in poise (P) or Pascal seconds (Pa-s); 1 Pa-s=10P.

C. Co-Polyetherimides

Useful polymers can also include co-polymers of a copolyetherimide having a glass transition temperature greater than or equal to about 218° C., said copolyetherimide comprising structural units of the formulas (I) and (II): 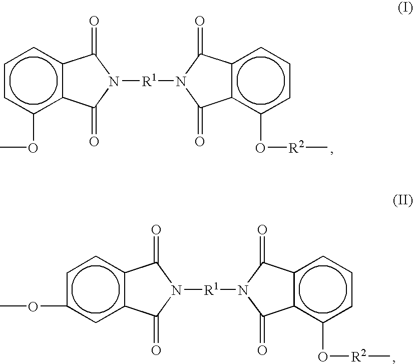
and optionally structural units of the formula (III): 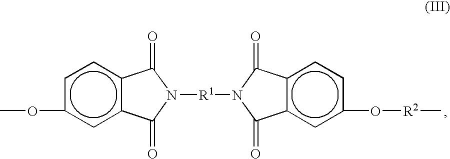
wherein R¹ comprises an unsubstituted C₆₋₂₂ divalent aromatic hydrocarbon or a substituted C₆₋₂₂ divalent aromatic hydrocarbon comprising halogen or alkyl substituents or mixtures of said substituents; or a divalent radical of the general formula (IV): 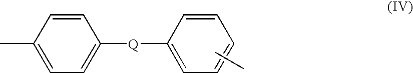
group wherein the unassigned positional isomer about the aromatic ring is either meta or para to Q, and Q is a covalent bond, a —C(CH₃)₂ or a member selected from the consisting of formulas (V): 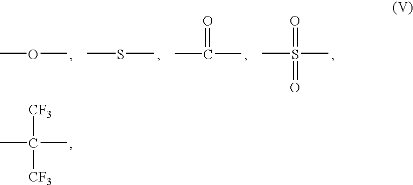
and an alkylene or alkylidene group of the formula C_{y}H_{2y}, wherein y is an integer having a value of 1 to about 5, and R is a divalent aromatic radical; the weight ratio of units of formula (I) to those of formula (II) being in the range of about 99.9:0.1 and about 25:75. Co-polymers having these elements are more fully discussed in U.S. Pat. No. 6,849,706, issued Feb. 1, 2005, in the names of Brunelle et al., titled “COPOLYETHERIMIDES”, herein incorporated by reference in its entirety as though set forth in full.

E. Other Additives to the Blend.

In addition to the polymer component of the blend, other beneficial compositions may be added to produce an improved article of manufacture. The skilled artisan will appreciate the wide range of ingredients which can be added to polymers to improve one or more manufacturing or performance property.

In some cases a metal oxide may be added to the polymers of the present invention. In some instances the metal oxide may further improve flame resistance (FR) performance by decreasing heat release and increasing the time to peak heat release. Titanium dioxide is of note. Other metal oxides include zinc oxides, boron oxides, antimony oxides, iron oxides and transition metal oxides. Metal oxides that are white may be desired in some instances. Metal oxides may be used alone or in combination with other metal oxides. Metal oxides may be used in any effective amount, in some instances at from 0.01 to about 20 wt % of the polymer blend.

Other useful additives include smoke suppressants such as metal borate salts for example zinc borate, alkali metal or alkaline earth metal borate or other borate salts. Additionally other of boron containing compounds, such as boric acid, borate esters, boron oxides or other oxygen compounds of boron may be useful. Additionally other flame retardant additives, such as aryl phosphates and brominated aromatic compounds, including polymers containing linkages made from brominated aryl compounds, may be employed. Examples of halogenated aromatic compounds, are brominated phenoxy resins, halogenated polystyrenes, halogenated imides, brominated polycarbonates, brominated epoxy resins and mixtures thereof.

Conventional flame retardant additives, for example, phosphate esters, sulfonate salts and halogenated aromatic compounds may also be employed. Mixtures of any or all of these flame retardants may also be used. Examples of halogenated aromatic compounds are brominated phenoxy resins, halogenated polystyrenes, halogenated imides, brominated polycarbonates, brominated epoxy resins and mixtures thereof. Examples of sulfonate salts are potassium perfluoro butyl sulfonate, sodium tosylate, sodium benzene sulfonate, sodium dichloro benzene sulfonate, potassium diphenyl sulfone sulfonate and sodium methane sulfonate. In some instances sulfonate salts of alkaline and alkaline earth metals are preferred. Examples of phosphate flame retardants are tri aryl phosphates, tri cresyl phosphate, triphenyl phosphate, bisphenol A phenyl diphosphates, resorcinol phenyl diphosphates, phenyl-bis-(3,5,5′-trimethylhexyl phosphate), ethyl diphenyl phosphate, bis(2-ethylhexyl)-p-tolyl phosphate, bis(2-ethylhexyl)-phenyl phosphate, tri(nonylphenyl)phosphate, phenyl methyl hydrogen phosphate, di(dodecyl)-p-tolyl phosphate, halogenated triphenyl phosphates, dibutyl phenyl phosphate, 2-chloroethyldiphenyl phosphate, p-tolyl bis(2,5,5′-trimethylhexyl)phosphate, 2-ethylhexyldiphenyl phosphate, diphenyl hydrogen phosphate, resorcinol diphosphate and the like. In some instances it maybe desired to have flame retardant compositions that are essentially free of halogen atoms, especially bromine and chlorine. Essentially free of halogen atoms means that in some embodiments the composition has less than about 3% halogen by weight of the composition and in other embodiments less than about 1% by weight of the composition containing halogen atoms. The amount of halogen atoms can be determined by ordinary chemical analysis. The composition may also optionally include a fluoropolymer in an amount of 0.01 to about 5.0% fluoropolymer by weight of the composition. The fluoro polymer may be used in any effective amount to provide anti-drip properties to the resin composition. Some possible examples of suitable fluoropolymers and methods for making such fluoropolymers are set forth, for example, in U.S. Pat. Nos. 3,671,487, 3,723,373 and 3,383,092. Suitable fluoropolymers include homopolymers and copolymers that comprise structural units derived from one or more fluorinated alpha-olefin monomers. The term “fluorinated alpha-olefin monomer” means an alpha-olefin monomer that includes at least one fluorine atom substituent. Some of the suitable fluorinated alpha-olefin monomers include, for example, fluoro ethylenes such as, for example, CF₂═CF₂, CHF═CF₂, CH₂═CF₂ and CH₂═CHF and fluoro propylenes such as, for example, CF₃CF═CF₂, CF₃CF═CHF, CF₃CH═CF₂, CF₃CH═CH₂, CF₃CF═CHF, CHF₂CH═CHF and CF₃CF═CH₂.

Some of the suitable fluorinated alpha-olefin copolymers include copolymers comprising structural units derived from two or more fluorinated alpha-olefin monomers such as, for example, poly(tetrafluoro ethylene-hexafluoro ethylene), and copolymers comprising structural units derived from one or more fluorinated monomers and one or more non-fluorinated monoethylenically unsaturated monomers that are copolymerizable with the fluorinated monomers such as, for example, poly(tetrafluoroethylene-ethylene-propylene) copolymers. Suitable non-fluorinated monoethylenically unsaturated monomers include for example, alpha-olefin monomers such as, for example, ethylene, propylene, butene, acrylate monomers such as for example, methyl methacrylate, butyl acrylate, and the like, with poly(tetrafluoroethylene) homopolymer (PTFE) preferred.

The blends may further contain fillers and reinforcements for example fiber glass, milled glass, glass beads, flake and the like. Minerals such as talc, wollastonite, mica, kaolin or montmorillonite clay, silica, quartz and barite may be added. The compositions can also be modified with effective amounts of inorganic fillers, such as, for example, carbon fibers and nanotubes, metal fibers, metal powders, conductive carbon, and other additives including nano-scale reinforcements. Other fillers well known to the skilled artisan, which may be conductive, may be employed to have the connector of the present invention provide shielding.

Other additives include, antioxidants such as phosphites, phosphonites and hindered phenols. Phosphorus containing stabilizers including triaryl phosphite and aryl phosphonates are of note as useful additives. Difunctional phosphorus containing compounds can also be employed. Stabilizers with a molecular weight of greater than or equal to about 300 are preferred. In other instances phosphorus containing stabilizers with a molecular weight of greater than or equal to 500 are useful. Phosphorus containing stabilizers are typically present in the composition at 0.05-0.5% by weight of the formulation. Colorants as well as light stabilizers and UV absorbers may also be present in the blend. Flow aids and mold release compounds are also contemplated. Examples of mold release agents are alkyl carboxylic acid esters, for example, pentaerythritol tetrastearate, glycerin tristearate and ethylene glycol distearate. Mold release agents are typically present in the composition at 0.05-0.5% by weight of the formulation. Preferred mold release agents will have high molecular weight, typically greater than about 300, to prevent loss of the release agent from the molten polymer mixture during melt processing.

Polymer blends used in articles according to the present invention may also include various additives such as nucleating, clarifying, stiffness and/or crystallization rate agents. These agents are used in a conventional matter and in conventional amounts.

3. Methods for Making Blends According to the Present Invention

The polymer blends used in articles according to the present invention can be blended with the aforementioned ingredients by a variety of methods involving intimate admixing of the materials with any additional additives desired in the formulation. A preferred procedure includes melt blending, although solution blending is also possible. Because of the availability of melt blending equipment in commercial polymer processing facilities, melt processing methods are generally preferred. Illustrative examples of equipment used in such melt processing methods include: co-rotating and counter-rotating extruders, single screw extruders, co-kneaders, disc-pack processors and various other types of extrusion equipment. The temperature of the melt in the present process is preferably minimized in order to avoid excessive degradation of the resins In some embodiments the melt processed composition exits processing equipment such as an extruder through small exit holes in a die, and the resulting strands of molten resin are cooled by passing the strands through a water bath. The cooled strands can be chopped and/or molded into any convenient shape, i.e. pellets, for packaging, further handling or ease of end use production.

The blends discussed herein can be prepared by a variety of melt blending techniques. Use of a vacuum vented single or twin screw extruder with a good mixing screw is preferred. In general, the melt processing temperature at which such an extruder should be run is about 100° to about 150° C. higher than the Tg of the thermoplastic. The mixture of ingredients may all be fed together at the throat of the extruder using individual feeders or as a mixture. In some cases, for instance in blends of two or more resins, it may be advantageous to first extrude a portion of the ingredients in a first extrusion and then add the remainder of the mixture in a second extrusion. It may be useful to first precompound the colorants into a concentrate which is subsequently mixed with the remainder of the resin composition. In other situations it may be beneficial to add portions of the mixture further down stream from the extruder throat. After extrusion the polymer melt can be stranded and cooled prior to chopping or dicing into pellets of appropriate size for the next manufacturing step. Preferred pellets are about 1/16 to ⅛ inch long, but the skilled artisan will appreciate that any pellet size will do. The pelletized thermoplastic resins are then dried to remove water and molded into the articles of the invention. Drying at about 135° to about 150° C. for about 4 to about 8 hours is preferred, but drying times will vary with resin type. Injection molding is preferred using suitable temperature, pressures, and clamping to produce articles with a glossy surface. Melt temperatures for molding will be about 1000 to about 200° C. above the T_{g} of the resin. Oil heated molds are preferred for higher Tg resins, Mold temperatures can range from about 50° to about 175° C. with temperatures of about 120° to about 175° C. preferred. The skilled artisan will appreciate the many variations of these compounding and molding conditions can be employed to make the compositions and articles of the invention.

### EXAMPLES

A bond core comprises either: a) an immiscible blend of polymers having more than one glass transition temperature and one of the polymers has a glass transition temperature greater than 180 degrees Celsius; b) a miscible blend of polymers having a single glass transition temperature greater than 217 degrees Celsius; or, c) a single virgin polymer having a glass transition temperature of greater than 247 degrees Celsius. The etched bond core has a thickness of 10 mils. The bond core is etched using a chemical method. A Nelco N4000-12 epoxy resin prepreg of 10 mils is laminated to each side of the bond core under standard lamination conditions and with standard lamination equipment.

In this example, fabric is impregnated with a resin that is either: a) an immiscible blend of polymers having more than one glass transition temperature and one of the polymers has a glass transition temperature greater than 180 degrees Celsius; b) a miscible blend of polymers having a single glass transition temperature greater than 217 degrees Celsius; or, c) a single virgin polymer having a glass transition temperature of greater than 247 degrees Celsius. The resin is forced into the reinforcement and the resin-impregnated reinforcement then traverses a heating tower where the combination is B-staged to yield a prepreg. Simultaneously, a copper foil approximately 1.4 mils thick is coated with approximately 2 mils of resin. This resin-coated copper is then applied to the prepreg and heated under pressure by means of a heated nip roll to yield the final product. This copper clad composite is of approximately 9-10 mil overall thickness and is cut into the requisite size printed wiring board.

While the invention has been illustrated and described in typical embodiments, it is not intended to be limited to the details shown, since various modifications and substitutions can be made without departing in any way from the spirit of the present invention. As such, further modifications and equivalents of the invention herein disclosed may occur to persons skilled in the art using no more than routine experimentation, and all such modifications and equivalents are believed to be within the spirit and scope of the invention as defined by the following claims. All patents, patent applications and other publications disclosed herein are incorporated by reference in their entirety as though set forth in full.

1. An electronic part comprising a composite material comprising an electrically conductive material disposed either over or under at least a portion of a substrate or coating respectively, wherein the substrate or coating comprises a material selected from the group consisting of: a) an immiscible blend of polymers comprising one or more polyetherimides, having more than one glass transition temperature wherein the polyetherimide has a glass transition temperature greater than 217° Celsius; b) a miscible blend of polymers, comprising one or more polyetherimides, having a single glass transition temperature greater than 180° Celsius; or, c) a single polyetherimide having a glass transition temperature of greater than 247° Celsius.

2. A composite material according to claim 1 wherein the polyetherimide has a hydrogen atom to carbon atom ratio of between about 0.4 and 0.85.

3. A composite material according to claim 1 wherein the polyetherimide is essentially free of benzylic protons.

4. The composite material according to claim 1 wherein the substrate comprises an immiscible blend of polymers having more than one glass transition temperature and one of the polymers has a glass transition temperature greater than 180° Celsius.

5. The composite material according to claim 1 wherein the substrate comprises a miscible blend of polymers having a single glass transition temperature greater than 217° Celsius.

6. The composite material according to claim 1 wherein the substrate comprises a single polymer having a glass transition temperature of greater than 2470 Celsius.

7. The composite material according to claim 1 wherein the substrate comprises a blend of a first resin selected from the group consisting of: polysulfones, polyether sulfones, polyphenylene ether sulfones, and mixtures thereof, a second resin comprising a silicone copolymer and a third resin comprising a resorcinol based aryl polyester resin wherein greater than or equal to 50 mole % of the aryl polyester linkages are aryl ester linkages derived from resorcinol.

8. The composite material according to claim 5 wherein the silicone copolymer is selected from the group consisting of; polyimide siloxanes, polyetherimide siloxanes, polyetherimide sulfone siloxanes, polycarbonate siloxanes, polyestercarbonate siloxanes, polysulfone siloxanes, polyether sulfone siloxanes, polyphenylene ether sulfone siloxanes and mixtures thereof.

9. The composite material according to 6 wherein the silicone copolymer content is from 0.1 to 10.0 wt % of the polymer blend.

10. The composite material according to 6 wherein the silicone copolymer has from 20-50 wt % siloxane content.

11. The composite material according to 5 wherein the polysulfones, polyether sulfones, polyphenylene ether sulfones and mixtures thereof, have a hydrogen atom to carbon atom ratio of less than or equal to 0.85.

12. The composite material according to claim 5 further comprising one or more metal oxides at 0.1 to 20% by weight of the polymer blend.

13. The composite material according to claim 5 wherein the resorcinol based aryl polyester has the structure shown below: 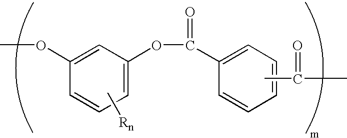
wherein R is at least one of C₁₋₁₂ alkyl, C₆-C₂₄ aryl, alkyl aryl, alkoxy or halogen; and, n is 0-4 and m is at least about 8.

14. The composite material according to claim 5 wherein the resorcinol based polyester resin is a copolymer containing carbonate linkages having the structure shown below: 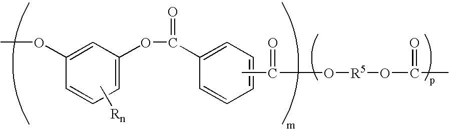
wherein R is at least one of C₁₋₁₂ alkyl, C₆-C₂₄ aryl, alkyl aryl, alkoxy or halogen, n is 0-4. R⁵ is at least one divalent organic radical, m is about 4-150 and p is about 2-200.

15. The composite material according to claim 12 wherein R⁵ is derived from a bisphenol compound.

16. A composite material according to claim 1 wherein the phase separated polymer blend comprises a mixture of: a) a first resin component selected from one or more of the group comprising: polyaryl ether ketones, polyaryl ketones, polyether ketones and polyether ether ketones; with, b) a second resin component comprising at least one polysulfone etherimide having greater than or equal to 50 mole % of the linkages containing at least one aryl sulfone group.

17. A composite material according to claim 14 wherein the polysulfone etherimide contains aryl sulfone and aryl ether linkages such that at least 50 mole % of the repeat units of the polysulfone etherimide contain at least one aryl ether linkage, at least one aryl sulfone linkage and at least two aryl imide linkages.

18. A composite material according to claim 14 wherein at least 50 mole % of the polysulfone etherimide linkages are derived from oxydiphthalic anhydride or a chemical equivalent thereof.

19. A composite material according to claim 14 wherein less than 30 mole % of polysulfone etherimide linkages are derived from a diamine or dianhydride containing an isoalkylidene group.

20. A composite material according to claim 14 wherein the substrate has a heat distortion temperature (HDT) of greater than or equal to 170° C., measured as per ASTM method D648 at 66 psi (0.46 Mpa) on a 3.2 mm sample.

21. A composite material according to claim 14 wherein the polysulfone etherimide is present from 30-70 wt % of the substrate.

22. A composite material according to claim 14 wherein the polysulfone etherimide is essentially free of benzylic protons.

23. A composite material according to claim 14 wherein the one or more polyaryl ether ketone, polyaryl ketone, polyether ketone, and polyether ether ketone have a crystalline melting point from 300° to 380° C.

24. A composite material according to claim 14 wherein the polysulfone etherimide has a glass transition temperature (Tg), from 250° to 350° C.

25. A composite material according to claim 14 wherein the polymer blend has at least two different glass transition temperatures, as measured by ASTM method D5418, wherein the first glass transition temperature is from 120°-200° C. and the second glass transition temperature is from 250°-350° C.

26. A composite material having improved flame retardance according to claim 1 wherein the substrate comprises a blend of a first resin selected from the group consisting of: polyimides, polyetherimides, polyetherimide sulfones, and mixtures thereof, a second resin comprising a silicone copolymer and a third resin comprising a resorcinol based aryl polyester resin wherein greater than or equal to 50 mole % of the aryl polyester linkages are aryl ester linkages derived from resorcinol.

27. A composite material according to claim 24 wherein the silicone copolymer is one or more selected from the group consisting of: polyimide siloxanes, polyetherimide siloxanes, polyetherimide sulfone siloxanes, polycarbonate siloxanes, polyestercarbonate siloxanes, polysulfone siloxanes, polyether sulfone siloxanes, and polyphenylene ether sulfone siloxanes.

28. A composite material according to claim 24 wherein the silicone copolymer content is from 0.1 to 10.0 wt % of the polymer blend.

29. A composite material according to claim 24 wherein the silicone copolymer has from 20-50 wt % siloxane content.

30. A composite material according to claim 24 wherein the polyimides, polyetherimides, polyetherimide sulfones and mixtures thereof, have a hydrogen atom to carbon atom ratio of less than or equal to 0.75.

31. A composite material according to claim 24 further comprising one or more metal oxides at 0.1 to 20% by weight of the polymer blend.

32. A composite material according to claim 24 wherein the resorcinol based aryl polyester has the structure shown below: 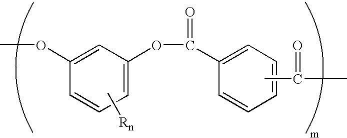
wherein R is at least one of C₁₋₁₂ alkyl, C₆-C₂₄ aryl, alkyl aryl, alkoxy or halogen, n is 0-4 and m is at least about 8.

33. A composite material according to claim 24 wherein the resorcinol based polyester resin is a copolymer containing carbonate linkages having the structure shown below: 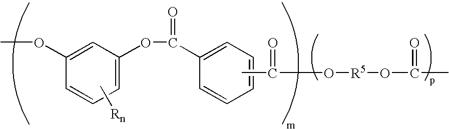
wherein R is at least one of C₁₋₁₂ alkyl, C₆-C₂₄ aryl, alkyl aryl, alkoxy or halogen, n is 0-4. R⁵ is at least one divalent organic radical, m is about 4-150 and p is about 2-200.

34. A composite material according to claim 31 wherein R⁵ is derived from a bisphenol compound.

35. A composite material according to claim 24 wherein the polyimide, polyetherimide, or polyetherimide sulfone is made from aryl dianhydrides selected from the group consisting of: bisphenol A dianhydride, oxydiphthalic anhydride, pyromellitic dianhydride, diphthalic anhydride, sulfonyl dianhydride, sulfur dianhydride, benzophenone dianhydride and mixtures thereof; and, aryl diamines selected from the group consisting of: meta phenylene diamine, para phenylene diamine, diamino diphenyl sulfone, oxydianiline, bis amino phenoxy benzene, bis aminophenoxy biphenyl, bis aminophenyl phenyl sulfone, diamino diphenyl sulfide and mixtures thereof.

36. A composite material according to claim 1 wherein the substrate comprises a copolyetherimide having a glass transition temperature of at least about 218° C., said copolyetherimide comprising structural units of the formulas (I) and (II): 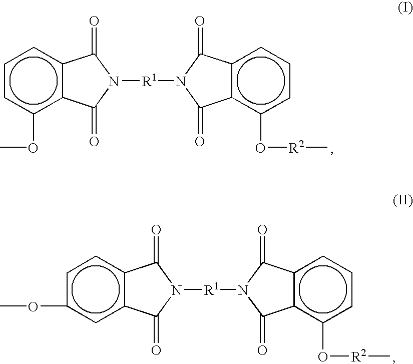
and optionally structural units of the formula (M): 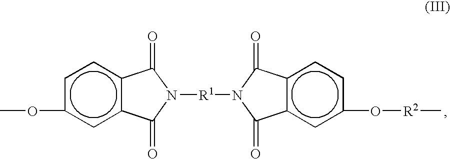
wherein R¹ comprises an unsubstituted C₆₋₂₂ divalent aromatic hydrocarbon or a substituted C₆₋₂₂ divalent aromatic hydrocarbon comprising halogen or alkyl substituents or mixtures of said substituents; or a divalent radical of the general formula (IV): 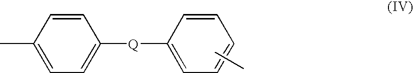
group wherein the unassigned positional isomer about the aromatic ring is either meta or para to Q, and Q is a covalent bond or a member selected from the consisting of formulas (V): 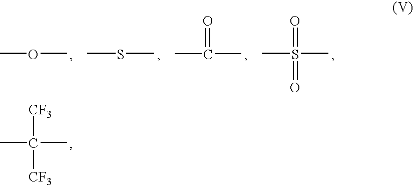
and an alkylene or alkylidene group of the formula C_{y}H_{2y}, wherein y is an integer from 1 to 5 inclusive, and R² is a divalent aromatic radical; the weight ratio of units of formula (I) to those of formula (II) being in the range of about 99.9:0.1 and about 25:75.

37. A composite material according to claim 34 comprising a copolyetherimide having a Tg greater than 225° C.

38. A composite material according to claim 34 comprising a copolyetherimide comprising structural units of the formula (III).

39. A composite material according to claim 34 wherein R¹ is derived from at least one diamine selected from the group consisting of meta-phenylenediamine; para-phenylenediamine; 2-methyl-4,6-diethyl-1,3-phenylenediamine; 5-methyl-4,6-diethyl-1,3-phenylenediamine; bis(4-aminophenyl)-2,2-propane; bis(2-chloro-4-amino-3,5-diethylphenyl)methane, 4,4′-diaminodiphenyl, 3,4′-diaminodiphenyl, 4,4′-diaminodiphenyl ether, 3,4′-diaminodiphenyl ether, 4,4′-diaminodiphenyl sulfone, 3,4′-diaminodiphenyl sulfone, 4,4′-diaminodiphenyl ketone, 3,4′-diaminodiphenyl ketone, 2,4-toluenediamine; and mixtures thereof.

40. A composite material according to claim 34 wherein R² is derived from at least one dihydroxy-substituted aromatic hydrocarbon of the formula (VI):
HO--D--OH
wherein D has the structure of formula (VII): 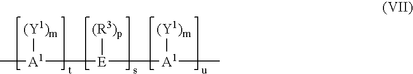
wherein A¹ represents an aromatic group;
E comprises a sulfur-containing linkage, sulfide, sulfoxide, sulfone; a phosphorus-containing linkage, phosphinyl, phosphonyl; an ether linkage; a carbonyl group; a tertiary nitrogen group; a silicon-containing linkage; silane; siloxy; a cycloaliphatic group; cyclopentylidene, 3,3,5-trimethylcyclopentylidene, cyclohexylidene, 3,3-dimethylcyclohexylidene, 3,3,5-trimethylcyclohexylidene, methylcyclohexylidene, 2-[2.2.1]-bicycloheptylidene, neopentylidene, cyclopentadecylidene, cyclododecylidene, adamantylidene; an alkylene or alkylidene group, which group may optionally be part of one or more fused rings attached to one or more aromatic groups bearing one hydroxy substituent; an unsaturated alkylidene group; or two or more alkylene or alkylidene groups connected by a moiety different from alkylene or alkylidene and selected from the group consisting of an aromatic linkage, a tertiary nitrogen linkage; an ether linkage; a carbonyl linkage; a silicon-containing linkage, silane, siloxy; a sulfur-containing linkage, sulfide, sulfoxide, sulfone; a phosphorus-containing linkage, phosphinyl, and phosphonyl;
R³ comprises hydrogen; a monovalent hydrocarbon group, alkenyl, allyl, alkyl, aryl, aralkyl, alkaryl, or cycloalkyl;
Y¹ independently at each occurrence is selected from the group consisting of an inorganic atom, a halogen; an inorganic group, a nitro group; an
organic group, a monovalent hydrocarbon group, alkenyl, allyl, alkyl, aryl, aralkyl, alkaryl, cycloalkyl, and an alkoxy group;
the letter “m” represents any integer from and including zero through the number of positions on A¹ available for substitution;
the letter “p” represents an integer from and including zero through the number of positions on E available for substitution;
the letter “t” represents an integer equal to at least one;
the letter “s” represents an integer equal to either zero or one; and,
“u” represents any integer including zero.

41. A composite material according to claim 34 wherein R² structural units in each of formulas (I), (II) and (III) are the same.

42. A composite material according to claim 34 wherein at least a portion of R² structural units in at least two of formulas (I), (II) and (III) are not the same.

43. A composite material according to claim 34 wherein R² is derived from at least one dihydroxy-substituted aromatic hydrocarbon selected from the group consisting of 4,4′-(cyclopentylidene)diphenol; 4,4′-(3,3,5-trimethylcyclopentylidene)diphenol; 4,4′-(cyclohexylidene)diphenol; 4,4′-(3,3-dimethylcyclohexylidene)diphenol; 4,4′-(3,3,5-trimethylcyclohexylidene)diphenol; 4,4′-(methylcyclohexylidene)diphenol; 4,4′-bis(3,5-dimethyl)diphenol, 1,1-bis(4-hydroxy-3-methylphenyl)cyclohexane; 4,4-bis(4-hydroxyphenyl)heptane; 2,4′-dihydroxydiphenylmethane; bis(2-hydroxyphenyl)methane; bis(4-hydroxyphenyl)methane; bis(4-hydroxy-5-nitrophenyl)methane; bis(4-hydroxy-2,6-dimethyl-3-methoxyphenyl)methane; 1,1-bis(4-hydroxyphenyl)ethane; 1,2-bis(4-hydroxyphenyl)ethane; 1,1-bis(4-hydroxy-2-chlorophenyl)ethane; 2,2-bis(4-hydroxyphenyl)propane; 2,2-bis(3-phenyl-4-hydroxyphenyl)propane; 2,2-bis(4-hydroxy-3-methylphenyl)propane; 2,2-bis(4-hydroxy-3-ethylphenyl)propane; 2,2-bis(4-hydroxy-3-isopropylphenyl)propane; 2,2-bis(4-hydroxy-3,5-dimethylphenyl)propane; 3,5,3′,5′-tetrachloro-4,4′-dihydroxyphenyl)propane; bis(4-hydroxyphenyl)cyclohexylmethane; 2,2-bis(4-hydroxyphenyl)-1-phenylpropane; 2,4′-dihydroxyphenyl sulfone; dihydroxy naphthalene, 2,6-dihydroxy naphthalene; hydroquinone; resorcinol; C₁₋₃ alkyl-substituted resorcinols; 2,2-bis-(4-hydroxyphenyl)butane; 2,2-bis-(4-hydroxyphenyl)-2-methylbutane; 1,1-bis-(4-hydroxyphenyl)cyclohexane; bis-(4-hydroxyphenyl); bis-(4-hydroxyphenyl)sulphide; 2-(3-methyl-4-hydroxyphenyl-2-(4-hydroxyphenyl)propane; 2-(3,5-dimethyl-4-hydroxyphenyl)-2-(4-hydroxyphenyl)propane; 2-(3-methyl-4-hydroxyphenyl)-2-(3,5-dimethyl-4-hydroxyphenyl)propane; bis-(3,5-dimethylphenyl-4-hydroxyphenyl)methane; 1,1-bis-(3,5-dimethylphenyl-4-hydroxyphenyl)ethane; 2,2-bis-(3,5-dimethylphenyl-4-hydroxyphenyl)propane; 2,4-bis-(3,5-dimethylphenyl-4-hydroxyphenyl)-2-methylbutane; 3,3-bis-(3,5-dimethylphenyl-4-hydroxyphenyl)pentane; 1,1-bis-(3,5-dimethylphenyl-4-hydroxyphenyl)cyclopentane; 1,1-bis-(3,5-dimethylphenyl-4-hydroxyphenyl)cyclohexane; bis-(3,5-dimethylphenyl-4-hydroxyphenyl)sulphide, 3-(4-hydroxyphenyl)-1,1,3-trimethylindan-5-ol, 1-(4-hydroxyphenyl)-1,3,3-trimethylindan-5-ol, and 2,2,2′,2′-tetrahydro-3,3,3′,3′-tetramethyl-1,1′-spirobi[1H-indene]-6,6′-diol.

44. A composite material according to claim 34 wherein R² is derived from at least one dihydroxy-substituted aromatic hydrocarbon selected from the group consisting of those of the formula (IX): 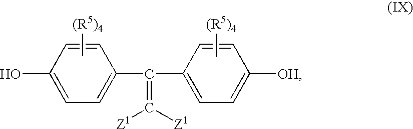
where independently each R⁵ is hydrogen, chlorine, bromine or a C₁₋₃₀ monovalent hydrocarbon or hydrocarbonoxy group, each Z¹ is hydrogen, chlorine or bromine, subject to the provision that at least one Z¹ is chlorine or bromine; and those of the formula (X): 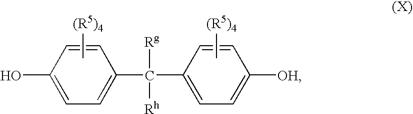
where independently each R⁵ is as defined hereinbefore, and independently R^{g} and R^{h} are hydrogen or a C₁₋₃₀ hydrocarbon group.

45. A composite material according to claim 42 wherein R² is derived from bisphenol A.

46. A composite material according to claim 34 further comprising structural units derived from at least one chain termination agent.

47. A composite material according to claim 44 wherein the chain termination agent is at least one unsubstituted or substituted member selected from the group consisting of alkyl halides, alkyl chlorides, aryl halides, aryl chlorides, and chlorides of formulas (XVII) and (XVIII): 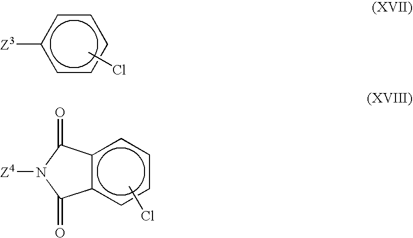
wherein the chlorine substituent is in the 3- or 4-position, and Z³ and Z⁴ comprise a substituted or unsubstituted alkyl or aryl group.

48. A composite material according to claim 45 wherein the chain termination agent is at least one member selected from the group consisting of monochlorobenzophenone, monochlorodiphenylsulfone; a monochlorophthalimide; 4-chloro-N-methylphthalimide, 4-chloro-N-butylphthalimide, 4-chloro-N-octadecylphthalimide, 3-chloro-N-methylphthalimide, 3-chloro-N-butylphthalimide, 3-chloro-N-octadecylphthalimide, 4-chloro-N-phenylphthalimide, 3-chloro-N-phenylphthalimide; a mono-substituted bis-phthalimide; a monochlorobisphthalimidobenzene; 1-[N-(4-chlorophthalimido)]-3-(N-phthalimido)benzene; 1-[N-(3-chlorophthalimido)]-3-(N-phthalimido)benzene; monochlorobisphthalimidodiphenyl sulfone, monochlorobisphthalimidodiphenyl ketone, a monochlorobisphthalimidophenyl ether; 4-[N-(4-chlorophthalimido)]phenyl-4′-(N-phthalimido)phenyl ether; 4-[N-(3-chlorophthalimido)phenyl]-4′-(N-phthalimido)phenyl ether, and the corresponding isomers of the latter two compounds derived from 3,4′-diaminodiphenyl ether.

49. A composite material according to claim 34 wherein the weight ratio of units of formula I to those of formula II is in the range of between about 99:1 and about 25:75.

50. A composite material according to claim 34 wherein the substrate has a heat distortion temperature at 0.455 mPa of at least 205° C.

51. A composite material according to claim 34 wherein the substrate has a heat distortion temperature at 0.455 mPa of at least 210° C.

52. A composite material according to claim 34 wherein the substrate has a temperature of transition between the brittle and ductile states of at most 30° C. as measured by ASTM method D3763.

53. The composite material according to claim 1 further comprising an adhesive layer disposed between the substrate and the electrically conductive material.

54. The composite material according to claim 1 wherein the electrically conductive material comprises a metal foil.

55. The composite material according to claim 1 wherein the electrically conductive material comprises a metal foil selected from the group consisting of copper, silver and gold.

56. The composite material according to claim 52 wherein the metal foil is copper foil.

57. The composite material according to claim 1 further comprising a cover layer disposed over the electrically conductive material.
